(19) United States
(12) Patent Application Publication
(10) Pub. No.: US 2025/0194215 A1
(43) Pub. Date: Jun. 12, 2025

(54) INTEGRATED CIRCUIT DEVICE

(71) Applicant: Samsung Electronics Co., Ltd., Suwon-si (KR)

(72) Inventors: Sangjine Park, Suwon-si (KR); Minhye Kim, Suwon-si (KR); Ilyoung Yoon, Suwon-si (KR)

(21) Appl. No.: 18/815,171

(22) Filed: Aug. 26, 2024

(30) Foreign Application Priority Data
Dec. 11, 2023 (KR) 10-2023-0178744

(51) Int. Cl. H01L 29/417; H01L 27/088; H01L 29/06; H01L 29/08; H01L 29/423; H01L 29/775; H01L 29/786

(52) U.S. Cl. CPC H10D 64/258; H10D 62/116; H10D 62/151; H10D 84/83; H10D 30/43; H10D 30/6735; H10D 30/6757; H10D 62/121

(57) ABSTRACT

Provided are an integrated circuit device and a method of manufacturing the same. The integrated circuit device includes a plurality of device isolation films spaced apart from each other, a gap-fill insulating film located between the plurality of device isolation films, a plurality of gate lines disposed above the gap-fill insulating film, a plurality of source/drain regions including a first source/drain region and a second source/drain region, each of the plurality of source/drain regions located between the plurality of gate lines, a backside contact provided below the first source/drain region, the backside contact extending through the gap-fill insulating film and electrically connected to the first source/drain region, and a gate protective film provided below the first source/drain region and being in contact with an upper sidewall of the backside contact. At least a portion of a sidewall of the gate protective film is surrounded by the gap-fill insulating film.

### CROSS-REFERENCE TO RELATED APPLICATION

This application claims priority under 35 U.S.C. § 119 to Korean Patent Application No. 10-2023-0178744, filed on Dec. 11, 2023, in the Korean Intellectual Property Office, the disclosure of which is incorporated by reference herein in its entirety.

### BACKGROUND

The inventive concept relates to an integrated circuit device, and more particularly, to an integrated circuit device having a structure formed in a self-aligned manner.

As electronic products become compact and multi-functional and require high performance, high capacity and high integration are required for integrated circuit devices. Accordingly, there is a need to efficiently design wiring structures to achieve the high integration while securing the functions and operating speed required for the integrated circuit devices.

### SUMMARY

Aspects of the inventive concept provide an integrated circuit device having improved reliability.

Also, the objects of the inventive concept are not limited to the aforementioned object, but other objects not described herein will be clearly understood by those skilled in the art from the following description.

According to an aspect of the inventive concept, there is provided an integrated circuit device including a plurality of device isolation films extending lengthwise in a first horizontal direction and spaced apart from each other in a second horizontal direction intersecting the first horizontal direction, a gap-fill insulating film located between the plurality of device isolation films, a plurality of gate lines disposed above the gap-fill insulating film and extending lengthwise in the second horizontal direction, a plurality of source/drain regions including a first source/drain region and a second source/drain region, each of the plurality of source/drain regions located between the plurality of gate lines, a backside contact provided below the first source/drain region, the backside contact extending through the gap-fill insulating film and electrically connected to the first source/drain region, and a gate protective film provided below the first source/drain region and being in contact with an upper sidewall of the backside contact, wherein at least a portion of a sidewall of the gate protective film is surrounded by the gap-fill insulating film.

According to another aspect of the inventive concept, there is provided an integrated circuit device including a plurality of device isolation films extending lengthwise in a first horizontal direction and spaced apart from each other in a second horizontal direction intersecting the first horizontal direction, a gap-fill insulating film located between the plurality of device isolation films, a plurality of gate lines disposed above the gap-fill insulating film and extending lengthwise in the second horizontal direction, a plurality of source/drain regions including a first source/drain region and a second source/drain region, each of the plurality of source/drain regions located between the plurality of gate lines, a gate dielectric film located between the plurality of source/drain regions and the plurality of gate lines, a gate protective film covering a portion of a lower surface of the gate dielectric film adjacent to the first source/drain region, a gap-fill gate protective film covering a portion of a lower surface of the gate dielectric film adjacent to the second source/drain region, and a backside contact being in contact with the gate protective film and electrically connected to the first source/drain region, wherein the gate protective film and the gap-fill gate protective film are arranged between the gap-fill insulating film and the plurality of source/drain regions.

According to another aspect of the inventive concept, there is provided an integrated circuit device including a plurality of device isolation films extending lengthwise in a first horizontal direction and spaced apart from each other in a second horizontal direction perpendicular to the first horizontal direction, a gap-fill insulating film located between two adjacent device isolation films among the plurality of device isolation films, at least one nanosheet disposed above the gap-fill insulating film, spaced apart from an upper surface of the gap-fill insulating film in a vertical direction, and facing the upper surface of the gap-fill insulating film, a gate line surrounding the at least one nanosheet above the gap-fill insulating film and extending lengthwise in the second horizontal direction intersecting the first horizontal direction, a gate dielectric film surrounding the gate line and separating the at least one nanosheet from the gate line, a first source/drain region and a second source/drain region, each disposed above the gap-fill insulating film and adjacent to the gate line and in contact with the at least one nanosheet, a backside contact extending from a level of a lower surface of the gap-fill insulating film in the vertical direction to a lower surface of the first source/drain region and covering a portion of the lower surface of the first source/drain region, a gate protective film located between the backside contact and the gap-fill insulating film and covering the other portion of the lower surface of the first source/drain region, and a source/drain contact provided above the second source/drain region and electrically connected to the second source/drain region, wherein the gap-fill insulating film includes a silicon oxide film, and the gate protective film includes a silicon carbide film.

### BRIEF DESCRIPTION OF THE DRAWINGS

Embodiments will be more clearly understood from the following detailed description taken in conjunction with the accompanying drawings in which:

FIG. 1 is a diagram illustrating a plan layout, as an example, of a cell block of an integrated circuit device according to embodiments;

FIG. 2 is a plan layout diagram illustrating the integrated circuit device according to embodiments;

FIG. 3A is a cross-sectional view of the integrated circuit device taken along line X1-X1′ in FIG. 2;

FIG. 3B is a cross-sectional view of the integrated circuit device taken along line Y1-Y1′ in FIG. 2;

FIG. 3C is a cross-sectional view of the integrated circuit device taken along line Y2-Y2′ of FIG. 2;

FIG. 3D is an enlarged cross-sectional view of region “EX2” of FIG. 3A;

FIG. 4A is a diagram illustrating an integrated circuit device according to some embodiments;

FIG. 4B is a diagram illustrating an integrated circuit device according to some embodiments;

FIG. 4C is a diagram illustrating an integrated circuit device according to some embodiments;

FIG. 4D is a diagram illustrating an integrated circuit device according to some embodiments;

FIG. 4E is a diagram illustrating an integrated circuit device according to some embodiments;

FIG. 5A is a diagram illustrating an integrated circuit device according to some embodiments;

FIG. 5B is a diagram illustrating an integrated circuit device according to some embodiments;

FIGS. 6, 7, 8A, 8B, 9A, 9B, 10, 11A, 11B, 12, 13A, 13B, 14 to 16, 17A, 17B, 18A, 18B, 19A, 19B, 20, 21, 22A, 22B, 23A, and 23B are diagrams illustrating, in a process order, a method of manufacturing an integrated circuit device, according to embodiments; and

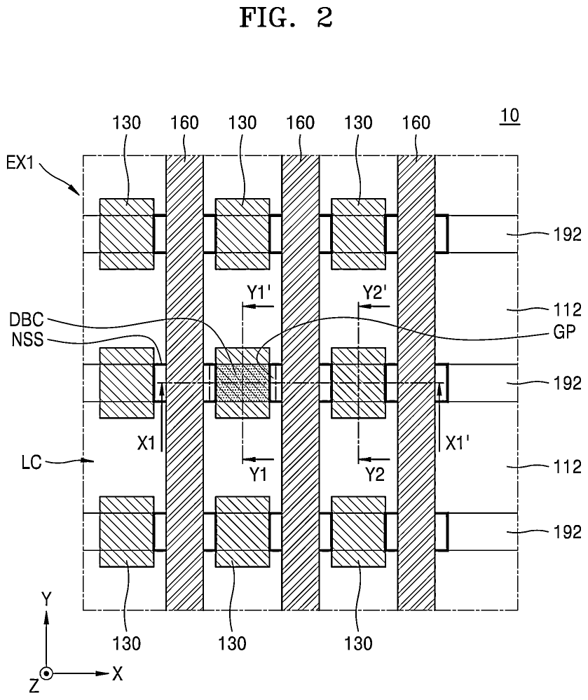

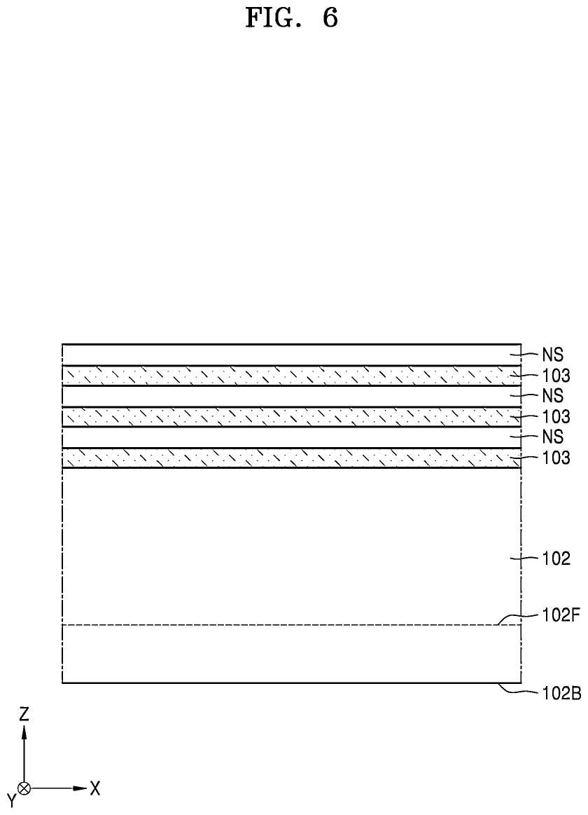

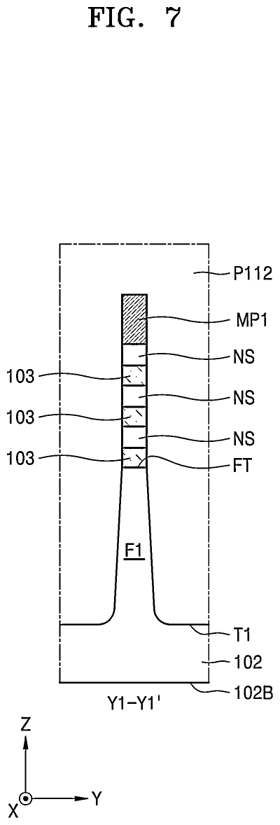

Specifically, FIGS. 6, 8A, 9A, 10, 11A, 13A, 14 to 16, 17A, 18A, 19A, 20, 21, 22A, and 23A are diagrams showing a manufacturing process corresponding to the cross-section taken along line X1-XF of FIG. 2, and FIGS. 7, 8B, 9B, 11B, 12, 13B, 17B, 18B, 19B, 22B and, 23B are diagrams showing a manufacturing process corresponding to the cross-section taken along line Y1-Y1′ of FIG. 2.

### DETAILED DESCRIPTION OF THE EMBODIMENTS

Advantages and features of the inventive concept and implementation methods thereof will be clarified through following embodiments described in detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. Further, the inventive concept is only defined by scopes of claims. The relative sizes of layers and regions in the drawings may be exaggerated for clarity of description. Like reference numerals refer to like elements throughout.

When one element is referred to as being “connected to” or “coupled to” another element, the one element can be directly connected or coupled to the other element or indirectly connected or coupled to the other element with an intervening element therebetween. On the other hand, when one element is referred to as being “directly connected to” or “directly coupled to” another element, there is no intervening element.

The term “and/or” includes any and all combinations of one or more of the associated listed items.

When an element or layer is referred to as being “above” or “on” another element or layer, the element or the layer can be directly on the other element or layer, or an intervening element or layer may also be present therebetween. On the other hand, when an element is referred to as being “directly on” or “directly above”, there is no intervening element or layer.

Although terms, such as first and second, are used to describe various elements, components, and/or sections, these elements, components, and/or sections are not limited by these terms. These terms are merely used to distinguish one element, component, or section from other elements, components, or sections. Therefore, a first element, a first component, or a first section described below may also be referred to as a second element, a second component, or a second section within the inventive concept.

The terms described herein are used only to explain embodiments while not limiting the inventive concept. In this specification, the singular forms include the plural forms as well, unless the context clearly indicates otherwise. The meaning of “comprises” and/or “comprising” used herein does not exclude the presence or addition of one or more components, steps, operations, and/or elements other than the mentioned components, steps, operations, and/or elements.

Unless otherwise defined, all terms (including technical and scientific terms) used herein have the same meaning as commonly understood by those skilled in the art to which the inventive concept belongs. Also, terms as defined in a generally used dictionary are not construed ideally or excessively unless defined apparently and specifically. Hereinafter, embodiments are described in detail with reference to the accompanying drawings.

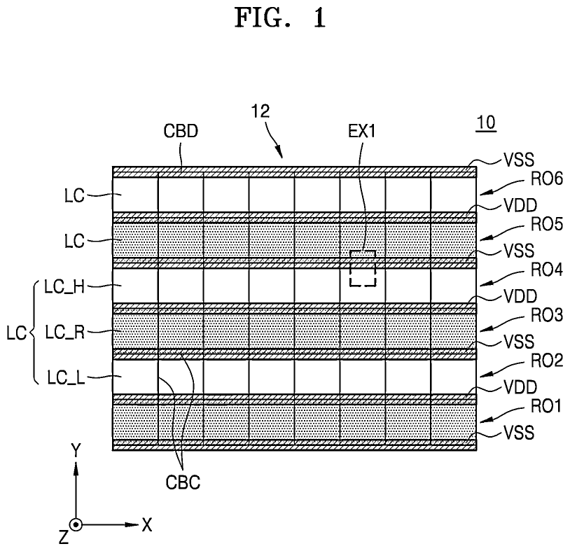

FIG. 1 is a diagram illustrating a plan layout, as an example, of a cell block 12 of an integrated circuit device 10 according to embodiments.

Referring to FIG. 1, the cell block 12 of the integrated circuit device 10 may include a plurality of logic cells LC including circuit patterns for constituting various circuits. The plurality of logic cells LC may be arranged in a matrix form in a first horizontal direction X and a second horizontal direction Y inside the cell block 12. The second horizontal direction Y may intersect the first horizontal direction X, e,g., may be perpendicular to the first horizontal direction X.

The plurality of logic cells LC may include a circuit pattern having a layout that is designed according to a place and route (PnR) technique to perform at least one logic function. The plurality of logic cells LC may perform various logic functions. In some embodiments, the plurality of logic cells LC may include a plurality of standard cells. In some embodiments, at least some of the plurality of logic cells LC may perform the same logic function. In some embodiments, at least some of the plurality of logic cells LC may perform different logic functions.

The plurality of logic cells LC may include various types of logic cells including a plurality of circuit elements. For example, each of the plurality of logic cells LC may include, but not limited to, an AND gate, a NAND gate, an OR gate, a NOR gate, an exclusive OR (XOR) gate, and/or an exclusive NOR (XNOR) gate, an inverter (INV), an adder (ADD), a buffer (BUF), a delay (DLY), a filter (FIL), a multiplexer (MXT/MXIT), an OR/AND/INVERTER (OAI), an AND/OR (AO) gate, an AND/OR/INVERTER (AOI), a D flip-flop, a reset flip-flop, a master-slave flip-flop, a latch, or a combination thereof.

In the cell block 12, at least some of the plurality of logic cells LC constituting one row RO1, RO2, RO3, RO4, RO5, or RO6 (or referred to as one of first to sixth rows RO1, RO2, RO3, RO4, RO5, and RO6) in the first horizontal direction X have the same width. Also, at least some of the plurality of logic cells LC constituting one row RO1, RO2, RO3, RO4, RO5, or RO6 may have the same height. However, the inventive concept is not limited to that illustrated in FIG. 1, and at least some of the plurality of logic cells LC constituting one row RO1, RO2, RO3, RO4, RO5, or RO6 may have different widths and different heights.

The area of each of the plurality of logic cells LC in the cell block 12 of the integrated circuit device 10 may be defined by a cell boundary CBD. A cell boundary contact region CBC may be provided between two logic cells LC adjacent to each other in the first horizontal direction X or the second horizontal direction Y among the plurality of logic cells LC, and the cell boundaries CBD of the two logic cells LC are in contact with each other in the cell boundary contact region CBC. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

In some embodiments, in the plurality of logic cells LC constituting one row RO1, RO2, RO3, RO4, RO5, or RO6, two logic cells LC adjacent to each other in the first horizontal direction X may be in contact with each other at the cell boundary contact region CBC with no separation distance therebetween. In some embodiments, in the plurality of logic cells LC constituting one row RO1, RO2, RO3, RO4, RO5, or RO6, two logic cells LC adjacent to each other in the first horizontal direction X may be spaced apart from each other with a certain distance therebetween.

In some embodiments, in the plurality of logic cells LC constituting one row RO1, RO2, RO3, RO4, RO5, or RO6, two logic cells LC adjacent to each other may perform the same function. In this case, two neighboring logic cells LC may have the same structure. In some embodiments, in the plurality of logic cells LC constituting one row RO1, RO2, RO3, RO4, RO5, or RO6, two logic cells LC adjacent to each other may perform different functions from each other.

In some embodiments, one logic cell LC selected from among the plurality of logic cells LC in the cell block 12 of the integrated circuit device 10 and another logic cell LC adjacent to the selected logic cell LC in the second horizontal direction Y (FIG. 1) may have symmetrical structures about the cell boundary contact region CBC therebetween. For example, a reference logic cell LC_R in the third row RO3 and a lower logic cell LC_L in the second row RO2 have symmetrical structures about the cell boundary contact region CBC therebetween. In addition, the reference logic cell LC_R in the third row RO3 and an upper logic cell LC_H in a fourth row RO4 have symmetrical structures about the cell boundary contact region CBC therebetween.

FIG. 1 shows that the cell block 12 includes six rows, such as the first to sixth rows RO1, RO2, RO3, RO4, RO5, and RO6, but this is only an example. The cell block 12 may include various numbers of rows selected as needed and the one row may include various numbers of logic cells selected as needed.

One selected from among a plurality of ground lines VSS and a plurality of power lines VDD may be located between the first to sixth rows RO1, RO2, RO3, RO4, RO5, and RO6 each including the plurality of logic cells LC arranged in a line in the first horizontal direction X. The plurality of ground lines VSS and the plurality of power lines VDD may each extend in the first horizontal direction X and may be arranged alternately while being spaced apart from each other in the second horizontal direction Y. Accordingly, the plurality of ground lines VSS and the plurality of power lines VDD may each overlap the cell boundary CBD of the logic cell LC in the vertical direction Z.

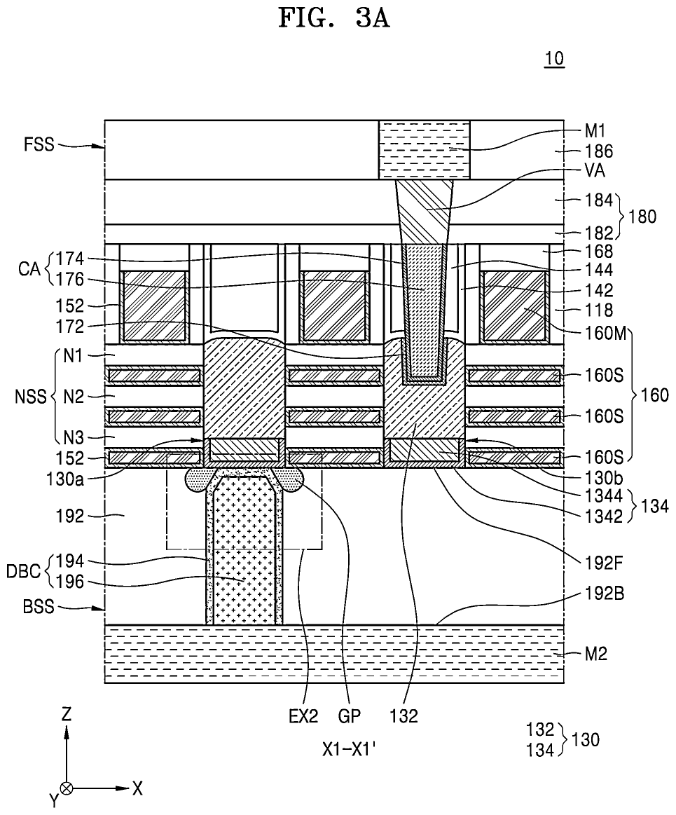

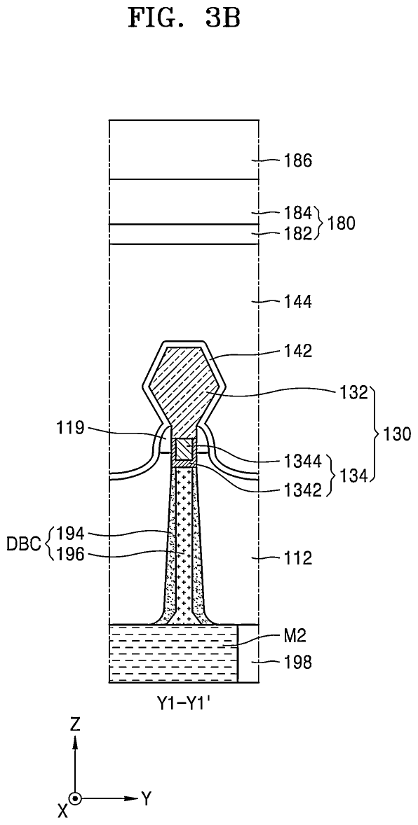

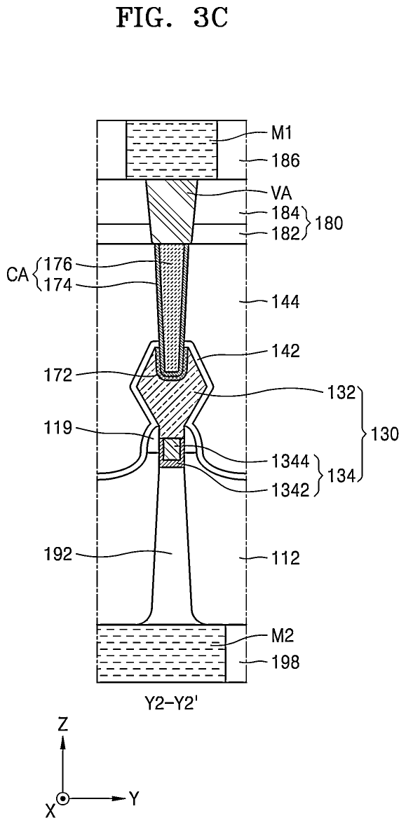

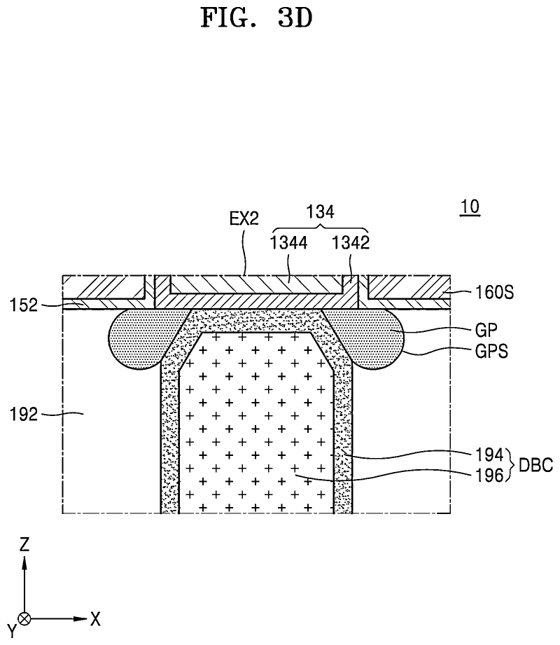

FIG. 2 is a plan layout diagram illustrating the integrated circuit device 10 according to embodiments. Specifically, FIG. 2 is an enlarged view of region “EX1” of FIG. 1. FIG. 3A is a cross-sectional view of the integrated circuit device 10 taken along line X1-X1′ shown in FIG. 2.

FIG. 3B is a cross-sectional view of the integrated circuit device 10 taken along line Y1-Y1′ shown in FIG. 2. FIG. 3C is a cross-sectional view of the integrated circuit device 10 taken along line Y2-Y2′ shown in FIG. 2. FIG. 3D is an enlarged cross-sectional view of region “EX2” of FIG. 3A.

An integrated circuit device 10 including a field effect transistor (FET) is described below with reference to FIGS. 2 and 3A to 3D. The FET has a gate-all-around structure that includes an active region in the form of a nanowire or nanosheet and a gate surrounding the active region. For example, the integrated circuit device 10 may include a multi-bridge channel FET (MBCFET) device. However, the inventive concept is not limited thereto, and the integrated circuit device 10 may include a planar FET device, a fin FET device, etc. The integrated circuit device 10 may include some of the plurality of logic cells LC illustrated in FIG. 1.

The integrated circuit device 10 may include a backside structure BSS and a front-side structure FSS disposed on the backside structure BSS. In some embodiments, the backside structure BSS may include a plurality of device isolation films 112, a plurality of gap-fill insulating films 192 each located between the plurality of device isolation films 112, a backside contact DBC, a gate protective film GP surrounding a portion of the upper sidewall of the backside contact DBC, and a lower wiring film M2 and a lower insulating film 198 on a back surface 192B of the gap-fill insulating film 192. The gap-fill insulating film 192 may surround the backside contact DBC.

In some embodiments, the front-side structure FSS may be disposed on a front surface 192F of the gap-fill insulating film 192 and include a plurality of nanosheet stacks NSS, a plurality of gate lines 160, a source/drain region 130 located between the plurality of gate lines 160, and an insulating liner 142 and an inter-gate insulating film 144 arranged above the source/drain region 130.

The front-side structure FSS of the integrated circuit device 10 may include an active structure. For example, the active structure may have a fin shape, nanowire shape, or nanosheet shape. FIGS. 3A to 3D illustrate that the active structure includes a nanosheet stack NSS, but the inventive concept is not limited thereto.

At a position spaced apart in a vertical direction Z from the front surface 192F of the gap-fill insulating film 192, the plurality of nanosheet stacks NSS may each include at least one nanosheet facing the front surface 192F of the gap-fill insulating film 192. The term “nanosheet” used herein refers to a conductive structure having a nanometer scale sheet shape substantially parallel to the direction in which current flows. It should be understood that the nanosheet includes or may be nanowires. Terms such as “same,” “equal,” “planar,” “parallel,” “perpendicular,” or “coplanar,” as used herein encompass identicality or near identicality including variations that may occur, for example, due to manufacturing processes. The term “substantially” may be used herein to emphasize this meaning, unless the context or other statements indicate otherwise.

The plurality of nanosheet stacks NSS may each include a first nanosheet N1, a second nanosheet N2, and a third nanosheet N3 which overlap each other in the vertical direction Z. The first nanosheet N1, the second nanosheet N2, and the third nanosheet N3 may have different vertical distances (Z distances) from the front surface 192F of the gap-fill insulating film 192. The plurality of gate lines 160 may each surround the first nanosheet N1, the second nanosheet N2, and the third nanosheet N3, which are in the nanosheet stack NSS and overlap each other in the vertical direction Z.

Although FIG. 2 illustrates a case in which the planar shape (a shape in a plan view) of the nanosheet stack NSS is approximately quadrangle, the inventive concept is not limited thereto. The nanosheet stack NSS may have various planar shapes depending on the planar shape of each of the gate lines 160. This example illustrates a configuration in which the plurality of nanosheet stacks NSS and the plurality of gate lines 160 are arranged above the gap-fill insulating film 192 and the plurality of nanosheet stacks NSS are arranged in a line above the gap-fill insulating film 192. However, the number of each of the nanosheet stacks NSS and gate lines 160 disposed above the gap-fill insulating film 192 is not particularly limited.

The first nanosheet N1, the second nanosheet N2, and the third nanosheet N3 in the nanosheet stack NSS may each function as a channel region. In some embodiments, the first nanosheet N1, the second nanosheet N2, and the third nanosheet N3 may each have a thickness selected within a range from about 4 nm to about 6 nm, but the inventive concept is not limited thereto. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range. Here, the thickness of each of the first nanosheet N1, the second nanosheet N2, and the third nanosheet N3 refers to the size in the vertical direction Z. In some embodiments, the first nanosheet N1, the second nanosheet N2, and the third nanosheet N3 may have substantially the same thickness in the vertical direction Z. In some embodiments, at least some of the first nanosheet N1, the second nanosheet N2, and the third nanosheet N3 may have different thicknesses in the vertical direction Z. In some embodiments, the first nanosheet N1, the second nanosheet N2, and the third nanosheet N3 in the nanosheet stack NSS may each include a Si layer, SiGe film, or a combination thereof.

As illustrated in FIG. 3A, the first nanosheet N1, the second nanosheet N2, and the third nanosheet N3 in one nanosheet stack NSS may have the same or similar sizes in the first horizontal direction X. In some embodiments, unlike the example in FIG. 3A, at least some of the first nanosheet N1, the second nanosheet N2, and the third nanosheet N3 in one nanosheet stack NSS have different sizes in the first horizontal direction X. In this example, a case in which each of the plurality of nanosheet stacks NSS includes three nanosheets is illustrated, but the inventive concept is not limited to the example. For example, the nanosheet stack NSS may include at least one nanosheet, and the number of nanosheets constituting the nanosheet stack NSS is not particularly limited.

As illustrated in FIG. 3A, the plurality of gate lines 160 may surround the plurality of nanosheet stacks NSS above the gap-fill insulating film 192 and extend lengthwise in the second horizontal direction Y. The plurality of gate lines 160 may extend parallel to each other. Each of the plurality of gate lines 160 may include a main gate portion 160M and a plurality of sub-gate portions 160S. The main gate portion 160M may cover the upper surface of the nanosheet stack NSS and extend lengthwise in the second horizontal direction Y. The plurality of sub-gate portions 160S may be integrally connected to the main gate portion 160M, e.g., without boundaries therebetween, and respectively arranged between the first nanosheet N1, the second nanosheet N2, and the third nanosheet N3 and between the third nanosheet N3 and the gap-fill insulating film 192. In the vertical direction Z, the thickness of each of the plurality of sub-gate portions 160S may be less than the thickness of the main gate portion 160M.

Each of the plurality of gate lines 160 may include or be formed of metal, metal nitride, metal carbide film, or a combination thereof. The metal may be selected from a group consisting of Ti, W, Ru, Nb, Mo, Hf, Ni, Co, Pt, Yb, Tb, Dy, Er, and Pd. The metal nitride may be selected from a group consisting of TiN and TaN. The metal carbide film may include or be formed of TiAlC. However, the material constituting the plurality of gate lines 160 is not limited to these examples.

A gate dielectric film 152 may be located between the nanosheet stack NSS and the gate line 160. In some embodiments, the gate dielectric film 152 may have a stack structure of an interface dielectric film and a high-k dielectric film. The interface dielectric film may include or may be a low-k dielectric material film having permittivity of about 9 or less, for example, a silicon oxide film, a silicon oxynitride film, or a combination thereof. In some embodiments, the interface dielectric film may be omitted. The high-k dielectric film may include or be formed of a material having a higher dielectric constant than the silicon oxide film. For example, the high-k dielectric film may have a dielectric constant of about 10 to about 25. The high-k dielectric film may include or may be a hafnium oxide film, but the inventive concept is not limited thereto.

Both sidewalls of each of the plurality of sub-gate portions 160S of the plurality of gate lines 160 may be spaced apart from the source/drain region 130 with the gate dielectric film 152 therebetween. The gate dielectric film 152 may be located between the sub-gate portion 160S of the gate line 160 and each of the first nanosheet N1, the second nanosheet N2, and the third nanosheet N3 and between the sub-gate portion 160S of the gate line 160 and the source/drain region 130.

According to embodiments, each of the gate dielectric film 152 and the gate line 160 may include a portion that overlaps (e.g., vertically) the plurality of nanosheet stacks NSS.

According to embodiments, a plurality of transistors may be formed in portions in which the plurality of nanosheet stacks NSS, the gate lines 160, and the gate dielectric film 152 overlap each other. According to embodiments, the plurality of transistors may include a p-channel metal-oxide semiconductor (PMOS) transistor and an n-channel metal-oxide semiconductor (NMOS) transistor. For example, each of the plurality of transistors may include at least one nanosheet stack NSS, a gate dielectric film 152 and gate line 160 surrounding the at least one nanosheet stack NSS, and a plurality of source/drain regions 130 facing the at least one nanosheet stack NSS in the first horizontal direction X.

In some embodiments, each of the plurality of nanosheet stacks NSS may include an undoped Si layer. In some other embodiments, each of the plurality of nanosheet stacks NSS may include a doped Si layer. For example, when the plurality of nanosheet stacks NSS constitutes or is included in a PMOS transistor, the plurality of nanosheet stacks NSS may each include a Si layer doped with a p-type dopant. Also, when the plurality of nanosheet stacks NSS constitutes or is included in an NMOS transistor, the plurality of nanosheet stacks NSS may each include a Si layer doped with an n-type dopant. The p-type dopant may be selected from a group consisting of boron (B) and gallium (Ga). The n-type dopant may be selected from a group consisting of phosphorus (P), arsenic (As), and antimony (Sb).

The upper surface of each of the gate dielectric film 152 and the gate line 160 may be covered with a capping insulating pattern 168. The capping insulating pattern 168 may include or may be a silicon nitride film or a silicon oxide film.

Both sidewalls of each of the gate line 160 and the capping insulating pattern 168 may be covered with an outer insulating spacer 118. The outer insulating spacer 118 may cover both sidewalls of the main gate portion 160M above the upper surface of the plurality of nanosheet stacks NSS. The outer insulating spacer 118 may be spaced apart from the gate line 160 with the gate dielectric film 152 therebetween.

As illustrated in FIGS. 3B and 3C, a plurality of recess-side insulating spacers 119 may be disposed on the upper surface of the device isolation film 112 so as to cover the sidewalls of the plurality of source/drain regions 130. In some embodiments, each of the plurality of recess-side insulating spacers 119 may be integrally connected to the outer insulating spacer 118 adjacent thereto, e.g., without boundaries therebetween.

Each of the plurality of outer insulating spacers 118 and the plurality of recess-side insulating spacers 119 may include or be formed of silicon nitride, a silicon oxide film, SiCN, SiBN, SiON, SiOCN, SiBCN, SiOC, or a combination thereof. Each of the terms “SiCN,” “SiBN,” “SiON,” “SiOCN,” “SiBCN,” and “SiOC” used herein indicates a material including elements shown in each term and is not a chemical formula representing stoichiometric relationships.

A metal silicide film 172 may be formed on the upper surface of each of the plurality of source/drain regions 130. The metal silicide film 172 may include metal including Ti, W, Ru, Nb, Mo, Hf, Ni, Co, Pt, Yb, Tb, Dy, Er, or Pd. For example, the metal silicide film 172 may include titanium silicide, but the inventive concept is not limited thereto.

The plurality of source/drain regions 130, the plurality of metal silicide films 172, and the plurality of outer insulating spacers 118 may be covered with the insulating liner 142. In some embodiments, the insulating liner 142 may be omitted. The inter-gate insulating film 144 may be disposed on the insulating liner 142. When the insulating liner 142 is omitted, the inter-gate insulating film 144 may be in contact with the plurality of source/drain regions 130.

The insulating liner 142 and the inter-gate insulating film 144 may be sequentially disposed on the plurality of source/drain regions 130 and the plurality of metal silicide films 172. The insulating liner 142 and the inter-gate insulating film 144 may constitute an insulating structure. In some embodiments, the insulating liner 142 may include or be formed of silicon nitride, SiCN, SiBN, SiON, SiOCN, SiBCN, or a combination thereof, but the inventive concept is not limited thereto. The inter-gate insulating film 144 may include or be formed of a silicon oxide film, but the inventive concept is not limited thereto.

As illustrated in FIGS. 3A to 3C, each of the plurality of source/drain regions 130 may be formed in a multi-layer structure. In some embodiments, each of the plurality of source/drain regions 130 may include or be formed of an upper source/drain region 132 and a lower source/drain region 134 below the upper source/drain region 132. For example, the lower source/drain region 134 may be disposed below the upper source/drain region 132 and in contact with the upper source/drain region 132. Also, the insulating liner 142 and the inter-gate insulating film 144 may be sequentially disposed above the upper source/drain region 132. In some embodiments, each of the plurality of source/drain regions 130 may not include the upper source/drain region 132 but include or be formed of only the lower source/drain region 134. For example, each of the plurality of source/drain regions 130 may include or be formed of a first semiconductor film 1342 and a second semiconductor film 1344, which are described below. For example, the insulating liner 142 and the inter-gate insulating film 144 may be sequentially disposed on the lower source/drain region 134.

In some embodiments, the contact surface of the upper source/drain region 132 and the lower source/drain region 134 may be located between the plurality of device isolation films 112 spaced apart from each other in the second horizontal direction Y. For example, the contact surface of the upper source/drain region 132 and the lower source/drain region 134 may be located between the device isolation films 112 in a plan view. In certain embodiments, the contact surface of the upper source/drain region 132 and the lower source/drain region 134 may overlap the device isolation films 112 in the second horizontal direction Y. In some embodiments, the contact surface of the upper source/drain region 132 and the lower source/drain region 134 may be located between (e.g., horizontally overlap) the plurality of recess-side insulating spacers 119 spaced apart from each other in the second horizontal direction Y.

The lower source/drain region 134 may include a first semiconductor film 1342 and a second semiconductor film 1344. The first semiconductor film 1342 may conformally extend along the sidewall and bottom of the second semiconductor film 1344. The first semiconductor film 1342 and the second semiconductor film 1344 together may be in contact with the upper source/drain region 132. The first semiconductor film 1342 may include a portion between the second semiconductor film 1344 and the backside contact DBC and the second semiconductor film 1344 may be spaced apart from the backside contact DBC with the portion of the first semiconductor film 1342 therebetween.

In some embodiments, the upper source/drain region 132 and lower source/drain region 134 may each include a silicon film or SiGe film. The term “SiGe” as used herein refers to a material composed of elements included in the term and is not a chemical formula representing a stoichiometric relationship. For example, each of the upper source/drain region 132 and the lower source/drain region 134 may include a single crystalline silicon film, a polycrystalline silicon film, an amorphous silicon film, a single crystalline SiGe film, a polycrystalline SiGe film, or an amorphous SiGe film. For example, the upper source/drain region 132 may include or be formed of a silicon film. Also, in the lower source/drain region 134, the first semiconductor film 1342 may include or may be a silicon film and the second semiconductor film 1344 may include or may be a SiGe film. In some embodiments, the upper source/drain region 132 may include or be formed of a SiGe film. In the lower source/drain region 134, both the first semiconductor film 1342 and the second semiconductor film 1344 may include or may be SiGe films, but the ratios/percentages of Ge contained in the first semiconductor film 1342 and the second semiconductor film 1344 may be different from each other.

In some embodiments, a first group of the plurality of source/drain regions 130 may constitute a PMOS transistor. In this case, in some embodiments, each of the upper source/drain region 132 and the lower source/drain region 134 may include a Si₁₋ₓGeₓ layer that is doped with a p-type dopant (where 0.0<x≤0.6).

In some embodiments, the content ratio or percentage of Ge in the upper source/drain region 132 may be greater than the content ratio or percentage of Ge in the lower source/drain region 134. In the lower source/drain region 134, the content ratio or percentage of Ge in the second semiconductor film 1344 may be greater than the content ratio or percentage of Ge in the first semiconductor film 1342. In some embodiments, the content ratio or atomic percentage of Ge in the first semiconductor film 1342 may be greater than about 0.0 at % and less than or equal to about 20 at %, for example, about 15 at % to about 30 at %. The content ratio or atomic percentage of Ge in the second semiconductor film 1344 may be about 30 at % to about 60 at %, for example, about 40 at % to about 60 at %. However, the inventive concept is not limited to these examples. In some embodiments, the p-type dopant may include or may be at least one selected from a group consisting of boron (B) and gallium (Ga), but the inventive concept is not limited thereto.

In some embodiments, a second group of the plurality of source/drain regions 130 may constitute an NMOS transistor. In this case, in some embodiments, each of the upper source/drain region 132 and the lower source/drain region 134 may include a Si layer doped with an n-type dopant, an undoped Si layer, or a combination thereof.

In some embodiments, the upper source/drain region 132 may include a Si layer doped with an n-type dopant and the lower source/drain region 134 may include a Si layer doped with an n-type dopant, an undoped Si layer, or a combination thereof. In the lower source/drain region 134, the first semiconductor film 1342 may include or be formed of an undoped Si layer and the second semiconductor film 1344 may include or be formed of a Si layer doped with an n-type dopant. In some embodiments, each of the upper source/drain region 132 and the lower source/drain region 134 may include a Si layer doped with an n-type dopant, and the content ratio or percentage of n-type dopant in the upper source/drain region 132 may be greater than the content ratio or percentage of n-type dopant in the lower source/drain region 134. In the lower source/drain region 134, each of the first semiconductor film 1342 and the second semiconductor film 1344 may include or be formed of a Si layer doped with an n-type dopant, and the content ratio or percentage of n-type dopant in the second semiconductor film 1344 may be greater than the content ratio or percentage of n-type dopant in the first semiconductor film 1342. The n-type dopant may include or may be at least one selected from a group consisting of phosphorus (P), arsenic (As), and antimony (Sb), but the inventive concept is not limited thereto.

In some embodiments, the plurality of source/drain regions 130 may include a first source/drain region 130a and a second source/drain region 130b. The first source/drain region 130a may be directly connected to the backside contact DBC and the second source/drain region 130b may be directly connected to a source/drain contact CA.

In some embodiments, the first source/drain region 130a and the second source/drain region 130b may be spaced apart from each other in the first horizontal direction X with one nanosheet stack NSS therebetween. For example, the first source/drain region 130a may function as a source region and the second source/drain region 130b may function as a drain region. In some embodiments, the first source/drain region 130a and the second source/drain region 130b may have the same shape as illustrated in FIG. 3A, but the inventive concept is not limited thereto. The first source/drain region 130a and the second source/drain region 130b may have different shapes from each other. For example, the first source/drain region 130a and the second source/drain region 130b may have different horizontal widths or different vertical thicknesses from each other.

As illustrated in FIG. 3A, the plurality of gate lines 160 may be disposed above the front surface 192F of the gap-fill insulating film 192. The gap-fill insulating film 192 may cover/contact at least a portion of the lower surface of the lowermost end of the gate dielectric film 152. Also, as illustrated in FIG. 2, the gap-fill insulating film 192 may be located between the plurality of device isolation films 112 spaced apart from each other and extend lengthwise in the first horizontal direction X.

In some embodiments, the gap-fill insulating film 192 may include or be formed of silicon nitride (SiN), silicon oxide film (SiO), SiCN, SiBN, SiON, SiOCN, SiBCN, SiOC, or a combination thereof, but the inventive concept is not limited to these examples. Each of the terms “SiN,” “SiO,” “SiCN,” “SiBN,” “SiON,” “SiOCN,” “SiBCN,” and “SiOC” used herein indicates a material including elements shown in each term and is not a chemical formula representing stoichiometric relationships. In some embodiments, the gap-fill insulating film 192 may include or be formed of a low-k dielectric film. The low-k dielectric film may include or be formed of fluorine-doped silicon oxide, organosilicate glass, carbon-doped oxide, porous silicon oxide, porous organosilicate glass, spin-on organic polymeric dielectric, spin-on silicon based polymeric dielectric, or a combination thereof, but the inventive concept is not limited to these examples.

In some embodiments, the backside contact DBC may be disposed below a source/drain region 130 selected from among the plurality of source/drain regions 130. For example, the backside contact DBC may be disposed below the first source/drain region 130a. The backside contact DBC may extend through the gap-fill insulating film 192, e.g., in a vertical direction, and come into contact with the first source/drain region 130a. The diagram illustrates that the upper surface of the backside contact DBC is on the same plane as the lower surface of the gate dielectric film 152, but the shape of the backside contact DBC is not limited to that illustrated in the diagram. For example, the backside contact DBC may extend further toward the first source/drain region 130a than shown in the diagram so that the backside contact DBC overlaps the first source/drain region 130a in the first horizontal direction X and the second horizontal direction Y. In some embodiments, the backside contact DBC may include or be formed of a backside barrier film 194 and a backside via 196.

In some embodiments, the backside barrier film 194 may include or be formed of metal or metal nitride. For example, the backside barrier film 194 may include or be formed of Ti, Ta, W, TiN, TaN, WN, WCN, TiSiN, TaSiN, WSiN, or a combination thereof, but the inventive concept is not limited thereto. The backside via 196 may include or be formed of molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but the inventive concept is not limited thereto.

Although not illustrated, a metal silicide film may be located between the backside barrier film 194 and the first source/drain region 130a. The metal silicide film may include metal including Ti, W, Ru, Nb, Mo, Hf, Ni, Co, Pt, Yb, Tb, Dy, Er, or Pd. The metal silicide film may be formed by consuming a portion of the first source/drain region 130a.

As illustrated in FIG. 3A, the backside contact DBC may be in contact with the gate protective film GP and the gap-fill insulating film 192 in the first horizontal direction X. For example, the gate protective film GP may cover the upper sidewall of the backside contact DBC in the first horizontal direction X and the gap-fill insulating film 192 may cover the lower sidewall of the backside contact DBC in the first horizontal direction X. The gate protective film GP may be surrounded by the source/drain region 130, the gate dielectric film 152, the gap-fill insulating film 192, and the backside contact DBC, e.g., in a cross-sectional view. Also, as illustrated in FIG. 3B, the backside contact DBC may be in contact with the device isolation film 112 in the second horizontal direction Y. For example, the device isolation film 112 may cover the sidewall of the backside contact DBC in the second horizontal direction Y.

In some embodiments, the horizontal width of the upper portion of the backside contact DBC in the first horizontal direction X may be less than the horizontal width of a lower portion of the backside contact DBC in the first horizontal direction X. For example, the horizontal width of the portion of the backside contact DBC overlapping the gate protective film GP in the first horizontal direction X may be less than the horizontal width of the portion of the backside contact DBC overlapping the gap-fill insulating film 192 in the first horizontal direction X.

In some embodiments, the gate protective film GP may cover/contact at least a portion of the lower surface of the lowermost end of the gate dielectric film 152. A portion of the lower surface of the gate dielectric film 152 covered by the gate protective film GP may be adjacent to the backside contact DBC. In some embodiments, the gate protective film GP may isolate the first source/drain region 130a from the gap-fill insulating film 192. For example, the gap-fill insulating film 192 may be spaced apart from the first source/drain region 130a with the gate protective film GP therebetween.

In some embodiments, the backside contact DBC may cover/contact a portion of the lower/bottom surface of the first source/drain region 130a and the gate protective film GP may cover the other portion of the lower/bottom surface of the first source/drain region 130a. For example, the horizontal width of the upper portion (e.g., at the top) of the backside contact DBC in the first horizontal direction X may be less than the horizontal width of the first source/drain region 130a in the first horizontal direction X. In some embodiments, the backside contact DBC may completely cover the lower surface of the first source/drain region 130a and the gate protective film GP may not cover/contact the lower surface of the first source/drain region 130a. For example, the horizontal width of the upper portion (e.g., at the top) of the backside contact DBC in the first horizontal direction X may be equal to or greater than the horizontal width of the first source/drain region 130a in the first horizontal direction X.

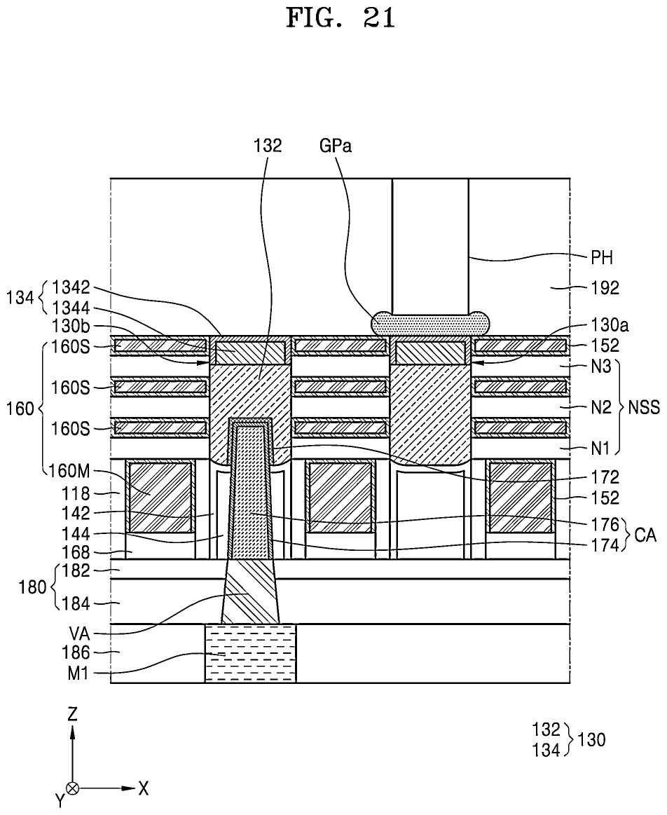

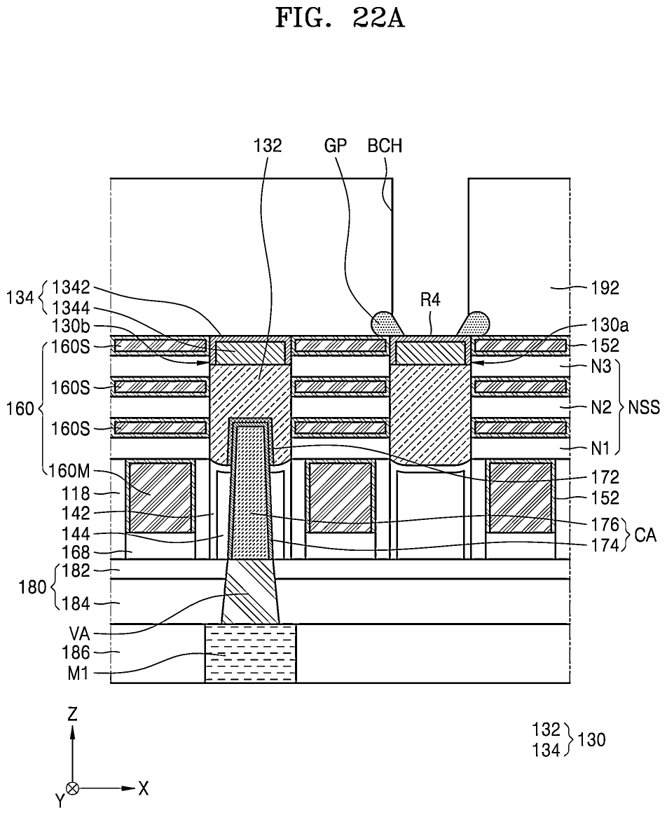

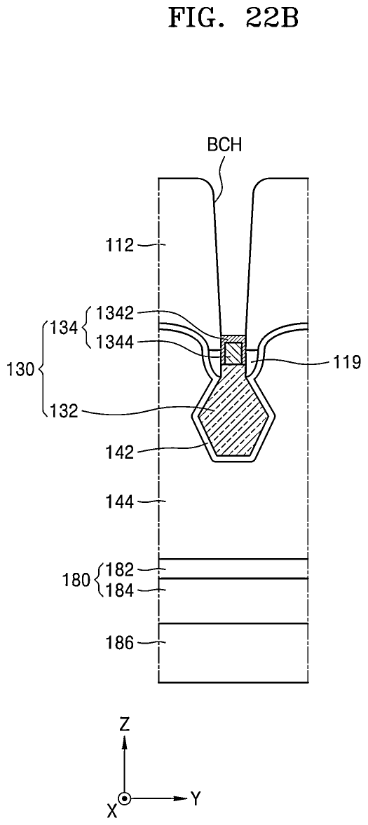

The gate protective film GP may include or may be a portion of a gap-fill gate protective film GPa (see FIG. 21) remaining after an etching process of forming a backside contact hole BCH (see FIG. 22A). The manufacturing process of the gate protective film GP is described below in detail with reference to FIGS. 21 and 22A.

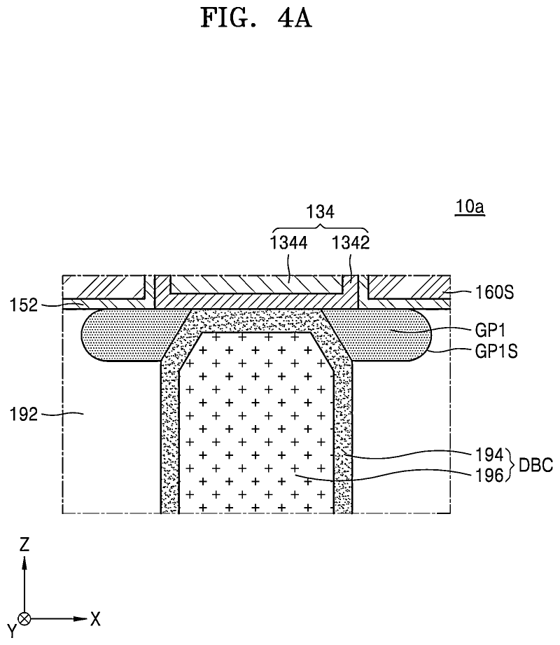

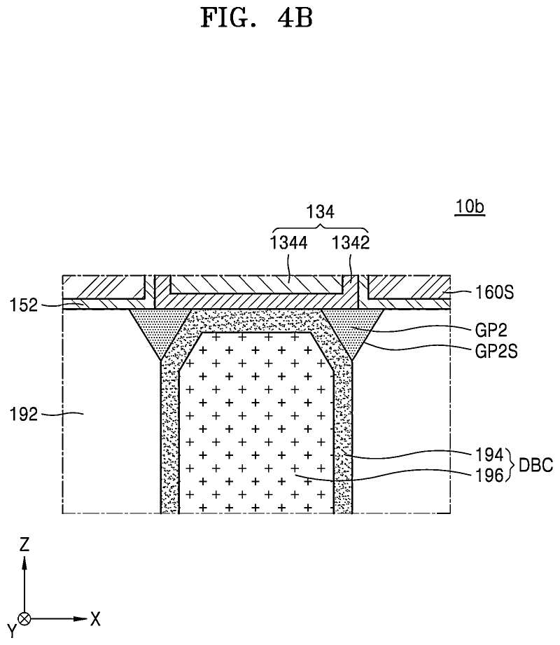

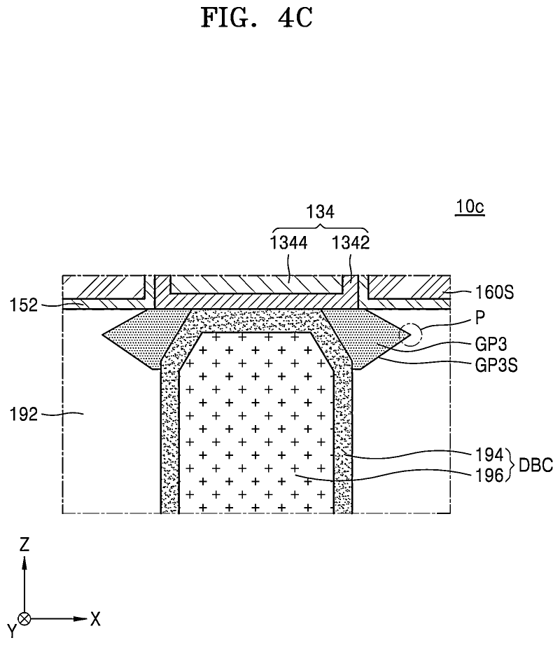

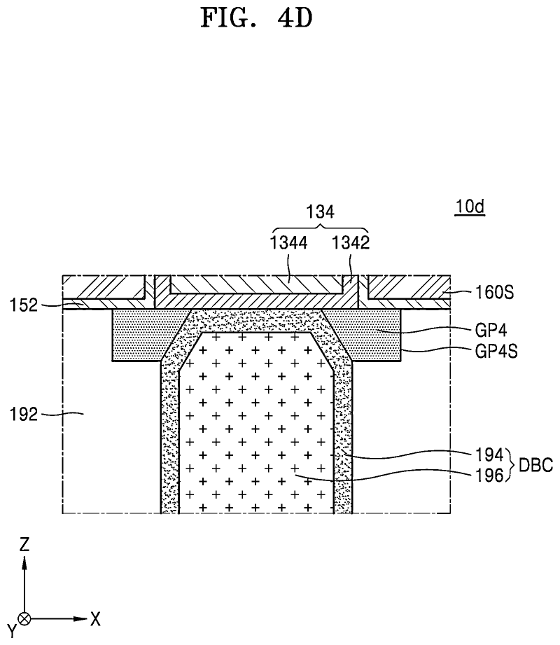

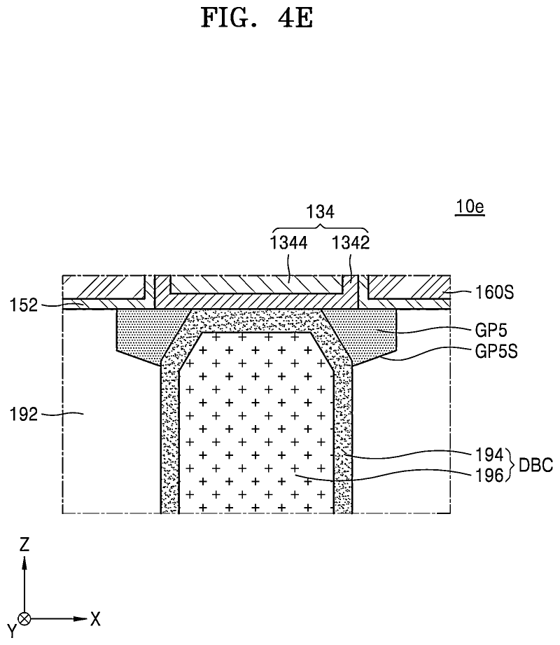

As illustrated in FIG. 3D, the upper surface of the gate protective film GP may be covered by the first source/drain region 130a and the gate dielectric film 152, and a sidewall GPS of the gate protective film GP opposite the backside contact DBC may be covered by the gap-fill insulating film 192. In some embodiments, the sidewall GPS of the gate protective film GP opposite the backside contact DBC may have a curved shape. For example, the sidewall GPS of the gate protective film GP opposite the backside contact DBC may not include a flat surface but include only a curved surface. The sidewall GPS of the gate protective film GP opposite the backside contact DBC may have a convex shape, e.g., protruding in a direction receding from the backside contact DBC. The shapes of the gate protective film GP are not limited to those shown in FIGS. 3A and 3D but may have various shapes. The shapes of the gate protective film GP are described below in detail with reference to FIGS. 4A, 4B, 4C, 4D, and 4E.

The gate protective film GP may include or be formed of a material having an etch selectivity to a fin-type active region F1 (see FIG. 7), which is described below. For example, the gate protective film GP may include or be formed of a material that has higher bonding energy than a material constituting the fin-type active region F1 (see FIG. 7).

In some embodiments, the gate protective film GP may include SiGeC, SiGe, SiC, SiO, SiOC, SiOCN, SiOH, GeC, or a combination thereof. In some embodiments, the gate protective film GP may be made of SiGeC, SiGe, SiC, SiO, SiOC, SiOCN, SiOH, GeC, or a combination thereof. As used herein, each of “SiGeC,” “SiGe,” “SiC,” “SiO,” “SiOC,” “SiOCN,” “SiOH,” “GeC” indicates a material including elements shown in each term and is not a chemical formula representing stoichiometric relationships. In some embodiments, the gate protective film GP may be single-crystalline, polycrystalline, or amorphous. In some embodiments, the gate protective film GP may include a single crystalline film formed through epitaxial growth.

For example, the gate protective film GP may include or be formed of SiC, and the carbon (C) content in the gate protective film GP may be selected from about 3 at % to about 30 at % or from about 3 at % to about 25 at %. However, this is only an example, and the carbon (C) content in the gate protective film GP may be adjusted if necessary. In some embodiments, the gate protective film GP may include a SiGe film, and a ratio of Ge contained in the gate protective film GP may be greater than a ratio of Ge contained in the first semiconductor film 1342.

As illustrated in FIG. 2, a pair of device isolation films 112 selected from among the plurality of device isolation films 112 may be spaced apart from each other with the gap-fill insulating film 192 therebetween. The plurality of device isolation films 112 may extend lengthwise in the first horizontal direction X and extend parallel to each other. The plurality of device isolation films 112 may be spaced apart from each other in the second horizontal direction Y. In some embodiments, each of the device isolation films 112 may include or may be a silicon oxide film, a silicon nitride film, a silicon oxynitride film, or a combination thereof. The backside contact DBC may be surrounded by the gap-fill insulating film 192 in the first horizontal direction X and surrounded by the device isolation film 112 in the second horizontal direction Y.

As shown in FIG. 3B, the device isolation film 112 may cover the sidewall of the backside contact DBC. In some embodiments, the device isolation film 112 and the plurality of recess-side insulating spacers 119 may cover lower portions of the sidewalls of the plurality of source/drain regions 130.

The source/drain contact CA may be disposed above a source/drain region 130 selected from among the plurality of source/drain regions 130. For example, the source/drain contact CA may be disposed above the second source/drain region 130b. Each of source/drain contacts CA may pass through the inter-gate insulating film 144 and the insulating liner 142 and come into contact with the metal silicide film 172. Each of the source/drain contacts CA may be electrically connected to the second source/drain region 130b via the metal silicide film 172. As used herein, components described as being “electrically connected” are configured such that an electrical signal can be transferred from one component to the other (although such electrical signal may be attenuated in strength as it transferred and may be selectively transferred). Each of the source/drain contacts CA may be spaced apart from the main gate portion 160M in the first horizontal direction X with the outer insulating spacer 118 therebetween.

The source/drain contact CA may include a conductive barrier pattern 174 and a contact plug 176, which are sequentially stacked above the second source/drain region 130b. The conductive barrier pattern 174 may be in contact with the bottom surface and sidewall of the contact plug 176 while surrounding the bottom surface and sidewall of the contact plug 176. Each of the source/drain contacts CA may extend lengthwise in the vertical direction Z and pass through the inter-gate insulating film 144 and the insulating liner 142. The conductive barrier pattern 174 may be located between the metal silicide film 172 and the contact plug 176. The conductive barrier pattern 174 may have a surface in contact with the metal silicide film 172 and a surface in contact with the contact plug 176. In some embodiments, the conductive barrier pattern 174 may include or be formed of metal or metal nitride. For example, the conductive barrier pattern 174 may include or be formed of Ti, Ta, W, TiN, TaN, WN, WCN, TiSiN, TaSiN, WSiN, or a combination thereof, but the inventive concept is not limited thereto. The contact plug 176 may include or be formed of molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but the inventive concept is not limited thereto.

The upper surface of each of the source/drain contacts CA, the plurality of capping insulating patterns 168, and the inter-gate insulating film 144 may be covered with an upper insulating structure 180. The upper insulating structure 180 may include an etch stop film 182 and an interlayer insulating film 184 which are sequentially stacked on each of the source/drain contacts CA, the plurality of capping insulating patterns 168, and the inter-gate insulating film 144. The etch stop film 182 may include or be formed of a silicon carbide film (SiC), SiN, nitrogen-doped silicon carbide film (SiC:N), SiOC, AlN, AlON, AlO, AlOC, or a combination thereof. The interlayer insulating film 184 may include or may be an oxide film, a nitride film, an ultra low-k (ULK) film having an ultra low dielectric constant K of about 2.2 to about 2.4, or a combination thereof. For example, the interlayer insulating film 184 may include or may be a tetraethylorthosilicate (TEOS) film, a high density plasma (HDP) oxide film, a boro-phospho-silicate glass (BPSG) film, a flowable chemical vapor deposition (FCVD) oxide film, an SiON film, an SiN film, an SiOC film, an SiCOH film, or a combination thereof, but the inventive concept is not limited thereto.

A source/drain via contact VA may be disposed on each of the source/drain contacts CA. Each of the source/drain via contacts VA may pass through the upper insulating structure 180 and come into contact with the source/drain contact CA. Each of the source/drain via contacts VA may be electrically connected to the second source/drain region 130b through the source/drain contact CA and the metal silicide film 172. The bottom surface of each of the source/drain via contacts VA may be in contact with the upper surface of the source/drain contact CA. Each of the source/drain via contacts VA may include or be formed of molybdenum (Mo) or tungsten (W), but the inventive concept is not limited thereto.

The upper surface of each of the upper insulating structure 180 and the source/drain via contact VA may be covered with an upper insulating film 186. The constituent materials of the upper insulating film 186 are the same or substantially the same as those described above with respect to the constituent materials of the interlayer insulating film 184.

An upper wiring layer M1 may pass through the upper insulating film 186 and be electrically connected to or contact the source/drain via contact VA which is located below the upper wiring layer M1. The upper wiring layer M1 may include or be formed of molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but the inventive concept is not limited thereto.

The lower surface of each of the device isolation film 112, the gap-fill insulating film 192, and the backside contact DBC may be covered with the lower insulating film 198. The constituent materials of the lower insulating film 198 are the same or substantially the same as those described above with respect to the constituent materials of the interlayer insulating film 184.

The lower wiring film M2 may pass through the lower insulating film 198 and be electrically connected to or contact the backside contact DBC, which is located on the upper portion of the lower wiring film M2. The lower wiring film M2 may include or be formed of molybdenum (Mo), copper (Cu), tungsten (W), cobalt (Co), ruthenium (Ru), manganese (Mn), titanium (Ti), tantalum (Ta), aluminum (Al), a combination thereof, or an alloy thereof, but the inventive concept is not limited thereto.

According to embodiments, the gate protective film GP covers the lower surface of the gate dielectric film 152 adjacent to the backside contact DBC, and thus, a portion of the gate dielectric film 152 adjacent to the backside contact DBC may be prevented from being etched during a process of forming the backside contact DBC, or etching of the gate dielectric film 152 may be reduced during the process of forming the backside contact DBC.

Also, the gate protective film GP and the backside contact DBC cover the lower surface of the first source/drain region 130a, and the gap-fill insulating film 192 is spaced apart from the first source/drain region 130a with the gate protective film GP and the backside contact DBC therebetween. Accordingly, the first source/drain region 130a may be prevented from being etched during the process of forming the backside contact DBC, or etching of the first source/drain region 130a may be reduced during the process of forming the backside contact DBC.

Consequently, defects in the integrated circuit device due to partial etching of the source/drain region 130, the gate dielectric film 152, and the gate line 160 may be prevented from occurring or may be reduced, thereby obtaining an integrated circuit device having improved reliability.

FIG. 4A is a diagram illustrating an integrated circuit device 10a according to some embodiments. FIG. 4A shows a portion of the integrated circuit device 10a corresponding to region “EX2” of FIG. 3A. In FIG. 4A, the same reference numerals as those in FIGS. 2 and 3A to 3D are given to the same members, and repeated descriptions thereof are omitted. The integrated circuit device 10a is different from the integrated circuit device 10 described above with reference to FIGS. 2 and 3A to 3D in that the integrated circuit device 10a includes a gate protective film GP1 instead of the gate protective film GP, and thus, the following description focuses on the differences therebetween.

Referring to FIG. 4A, the integrated circuit device 10a may include the gate protective film GP1. A portion of the sidewall of the backside contact DBC may be covered by the gate protective film GP1 and the other portion of the sidewall of the backside contact DBC may be covered by the gap-fill insulating film 192. For example, the gate protective film GP1 may cover the upper sidewall of the backside contact DBC and the gap-fill insulating film 192 may cover the lower sidewall of the backside contact DBC. The gate protective film GP1 may be surrounded by the first source/drain region 130a, the gate dielectric film 152, the gap-fill insulating film 192, and the backside contact DBC.

In some embodiments, the gate protective film GP1 may cover at least a portion of the lower surface of the lowermost end of the gate dielectric film 152. A portion of the lower surface of the gate dielectric film 152 covered by the gate protective film GP1 may be adjacent to the backside contact DBC. In some embodiments, the gate protective film GP1 may isolate the first source/drain region 130a from the gap-fill insulating film 192. For example, the gap-fill insulating film 192 may be spaced apart from the first source/drain region 130a with the gate protective film GP1 therebetween.

In some embodiments, the backside contact DBC may cover a portion of the lower surface of the first source/drain region 130a and the gate protective film GP1 may cover the other portion of the lower surface of the first source/drain region 130a. For example, the horizontal width of the upper portion of the backside contact DBC in the first horizontal direction X may be less than the horizontal width of the first source/drain region 130a in the first horizontal direction X. In some embodiments, the backside contact DBC may completely cover the lower surface of the first source/drain region 130a and the gate protective film GP1 may not cover/contact the lower surface of the first source/drain region 130a. For example, the horizontal width of the upper portion of the backside contact DBC in the first horizontal direction X may be equal to or greater than the horizontal width of the first source/drain region 130a in the first horizontal direction X.

The gate protective film GP1 may include or may be a portion of a gap-fill gate protective film GPa (see FIG. 21) remaining after an etching process of forming the backside contact hole BCH (see FIG. 22A). The manufacturing process of the gate protective film GP1 is described below in detail with reference to FIGS. 21 and 22A.

As illustrated in FIG. 4A, the upper surface of the gate protective film GP1 may be covered by the first source/drain region 130a and the gate dielectric film 152, and a sidewall GP1S of the gate protective film GP1 opposite the backside contact DBC may be covered by the gap-fill insulating film 192. In some embodiments, the sidewall GP1S of the gate protective film GP1 opposite the backside contact DBC may have a curved shape. For example, the sidewall GP1S of the gate protective film GP1 may include a combination of a flat surface and a curved surface. For example, the sidewall GP1S of the gate protective film GP1 may include a combination of the flat surface that extends from the sidewall of the backside contact DBC in a direction intersecting the sidewall of the backside contact DBC, and the curved surface that faces away from the sidewall of the backside contact DBC, e.g., in a cross-sectional view. The sidewall GP1S of the gate protective film GP1 opposite the backside contact DBC may have a shape that is convex protruding in a direction receding from the sidewall of the backside contact DBC.

FIG. 4B is a diagram illustrating an integrated circuit device 10b according to some embodiments. FIG. 4B shows a portion of the integrated circuit device 10b corresponding to region “EX2” of FIG. 3A. In FIG. 4B, the same reference numerals as those in FIGS. 2 and 3A to 3D are given to the same members, and repeated descriptions thereof are omitted. The integrated circuit device 10b is different from the integrated circuit device 10 described above with reference to FIGS. 2 and 3A to 3D in that the integrated circuit device 10b includes a gate protective film GP2 instead of the gate protective film GP, and thus, the following description focuses on the differences therebetween.

Referring to FIG. 4B, the integrated circuit device 10b may include the gate protective film GP2. A portion of the sidewall of the backside contact DBC may be covered by the gate protective film GP2 and the other portion of the sidewall of the backside contact DBC may be covered by the gap-fill insulating film 192. For example, the gate protective film GP2 may cover the upper sidewall of the backside contact DBC and the gap-fill insulating film 192 may cover the lower sidewall of the backside contact DBC. The gate protective film GP2 may be surrounded by the first source/drain region 130a, the gate dielectric film 152, the gap-fill insulating film 192, and the backside contact DBC.

In some embodiments, the gate protective film GP2 may cover/contact at least a portion of the lower surface of the lowermost end of the gate dielectric film 152. A portion of the lower surface of the gate dielectric film 152 covered by the gate protective film GP2 may be adjacent to the backside contact DBC.

In some embodiments, the backside contact DBC may cover/contact a portion of the lower surface of the first source/drain region 130a and the gate protective film GP2 may cover/contact the other portion of the lower surface of the first source/drain region 130a. For example, the horizontal width of the upper portion of the backside contact DBC in the first horizontal direction X may be less than the horizontal width of the first source/drain region 130a in the first horizontal direction X. In some embodiments, the backside contact DBC may completely cover the lower surface of the first source/drain region 130a and the gate protective film GP2 may not cover/contact the lower surface of the first source/drain region 130a. For example, the horizontal width of the upper portion of the backside contact DBC in the first horizontal direction X may be equal to or greater than the horizontal width of the first source/drain region 130a in the first horizontal direction X.

The gate protective film GP2 may include or may be a portion of a gap-fill gate protective film GPa (see FIG. 21) remaining after an etching process of forming the backside contact hole BCH (see FIG. 22A). The manufacturing process of the gate protective film GP2 is described below in detail with reference to FIGS. 21 and 22A.

As illustrated in FIG. 4B, the upper surface of the gate protective film GP2 may be covered by the first source/drain region 130a and the gate dielectric film 152, and a sidewall GP2S of the gate protective film GP2 opposite the backside contact DBC may be covered by the gap-fill insulating film 192. In some embodiments, the sidewall GP2S of the gate protective film GP2 opposite the backside contact DBC may have a flat/plane surface. For example, the sidewall GP2S of the gate protective film GP2 opposite the backside contact DBC may include only a flat/plane surface, e.g., in a cross-sectional view. Sidewalls GP2S of the gate protective film GP2 may include a flat/plane surface that extends from the sidewall of the backside contact DBC in a direction intersecting the sidewall of the backside contact DBC. For example, the side walls GP2S may include an inclined surface. The sidewall GP2S of the gate protective film GP2 opposite the backside contact DBC may recede from the sidewall of the backside contact DBC in a direction moving from the bottom to the top of the sidewall GP2S. A top surface of the gate protective film GP2 may also be flat.

FIG. 4C is a diagram illustrating an integrated circuit device 10c according to some embodiments. FIG. 4C shows a portion of the integrated circuit device 10c corresponding to region “EX2” of FIG. 3A. In FIG. 4C, the same reference numerals as those in FIGS. 2 and 3A to 3D are given to the same members, and repeated descriptions thereof are omitted. The integrated circuit device 10c is different from the integrated circuit device 10 described above with reference to FIGS. 2 and 3A to 3D in that the integrated circuit device 10c includes a gate protective film GP3 instead of the gate protective film GP, and thus, the following description focuses on the differences therebetween.

Referring to FIG. 4C, the integrated circuit device 10c may include the gate protective film GP3. A portion of the sidewall of the backside contact DBC may be covered by the gate protective film GP3 and the other portion of the sidewall of the backside contact DBC may be covered by the gap-fill insulating film 192. For example, the gate protective film GP3 may cover the upper sidewall of the backside contact DBC and the gap-fill insulating film 192 may cover the lower sidewall of the backside contact DBC. The gate protective film GP3 may be surrounded by or contact the first source/drain region 130a, the gate dielectric film 152, the gap-fill insulating film 192, and the backside contact DBC.

In some embodiments, the gate protective film GP3 may cover at least a portion of the lower surface of the lowermost end of the gate dielectric film 152. A portion of the lower surface of the gate dielectric film 152 covered by the gate protective film GP3 may be adjacent to the backside contact DBC.

In some embodiments, the backside contact DBC may cover a portion of the lower surface of the first source/drain region 130a and the gate protective film GP3 may cover the other portion of the lower surface of the first source/drain region 130a. For example, the horizontal width of the upper portion of the backside contact DBC in the first horizontal direction X may be less than the horizontal width of the first source/drain region 130a in the first horizontal direction X. In some embodiments, the backside contact DBC may completely cover the lower surface of the first source/drain region 130a and the gate protective film GP3 may not cover (e.g., may not contact) the lower surface of the first source/drain region 130a. For example, the horizontal width of the upper portion of the backside contact DBC in the first horizontal direction X may be equal to or greater than the horizontal width of the first source/drain region 130a in the first horizontal direction X.

The gate protective film GP3 may include or may be a portion of a gap-fill gate protective film GPa (see FIG. 21) remaining after an etching process of forming the backside contact hole BCH (see FIG. 22A). The manufacturing process of the gate protective film GP3 is described below in detail with reference to FIGS. 21 and 22A.

As illustrated in FIG. 4C, the upper surface of the gate protective film GP3 may be covered by the first source/drain region 130a and the gate dielectric film 152, and a sidewall GP3S of the gate protective film GP3 opposite the backside contact DBC may be covered by the gap-fill insulating film 192. In some embodiments, the sidewall GP3S of the gate protective film GP3 opposite the backside contact DBC may have a pointy/pointed or angular shape, e.g., having an acute angle in a cross-sectional view. For example, the sidewall GP3S of the gate protective film GP3 opposite the backside contact DBC may include a vertex P. The sidewall GP3S of the gate protective film GP3 opposite the backside contact DBC may recede from the sidewall of the backside contact DBC in a direction approaching the vertex P from top and bottom of the gate protective film GP3.

FIG. 4D is a diagram illustrating an integrated circuit device 10d according to some embodiments. FIG. 4D shows a portion of the integrated circuit device 10d corresponding to region “EX2” of FIG. 3A. In FIG. 4D, the same reference numerals as those in FIGS. 2 and 3A to 3D are given to the same members, and repeated descriptions thereof are omitted. The integrated circuit device 10d is different from the integrated circuit device 10 described above with reference to FIGS. 2 and 3A to 3D in that the integrated circuit device 10d includes a gate protective film GP4 instead of the gate protective film GP, and thus, the following description focuses on the differences therebetween.

Referring to FIG. 4D, the integrated circuit device 10d may include the gate protective film GP4. A portion of the sidewall of the backside contact DBC may be covered by the gate protective film GP4 and the other portion of the sidewall of the backside contact DBC may be covered by the gap-fill insulating film 192. For example, the gate protective film GP4 may cover/contact the upper sidewall of the backside contact DBC and the gap-fill insulating film 192 may cover/contact the lower sidewall of the backside contact DBC. The gate protective film GP4 may be surrounded by or contact the first source/drain region 130a, the gate dielectric film 152, the gap-fill insulating film 192, and the backside contact DBC.

In some embodiments, the gate protective film GP4 may cover/contact at least a portion of the lower surface of the lowermost end of the gate dielectric film 152. A portion of the lower surface of the gate dielectric film 152 covered by the gate protective film GP4 may be adjacent to the backside contact DBC.

In some embodiments, the backside contact DBC may cover/contact a portion of the lower surface of the first source/drain region 130a and the gate protective film GP4 may cover/contact the other portion of the lower surface of the first source/drain region 130a. For example, the horizontal width of the upper portion of the backside contact DBC in the first horizontal direction X may be less than the horizontal width of the first source/drain region 130a in the first horizontal direction X. In some embodiments, the backside contact DBC may completely cover the lower surface of the first source/drain region 130a and the gate protective film GP4 may not cover (e.g., may not contact) the lower surface of the first source/drain region 130a. For example, the horizontal width of the upper portion of the backside contact DBC in the first horizontal direction X may be equal to or greater than the horizontal width of the first source/drain region 130a in the first horizontal direction X.

The gate protective film GP4 may include or may be a portion of a gap-fill gate protective film GPa (see FIG. 21) remaining after an etching process of forming the backside contact hole BCH (see FIG. 22A). The manufacturing process of the gate protective film GP4 is described below in detail with reference to FIGS. 21 and 22A.

As illustrated in FIG. 4D, the upper surface of the gate protective film GP4 may be covered by and/or contact the first source/drain region 130a and the gate dielectric film 152, and a sidewall GP4S of the gate protective film GP4 opposite the backside contact DBC may be covered by the gap-fill insulating film 192. In some embodiments, the sidewall GP4S of the gate protective film GP4 opposite the backside contact DBC may have a flat/plane surface. For example, the sidewall/surfaces GP4S of the gate protective film GP4 may include only a plurality of flat surfaces extending in different directions, e.g., in a cross-sectional view. For example, the sidewall/surfaces GP4S of the gate protective film GP4 may include a first flat surface that extends from the sidewall of the backside contact DBC in a direction intersecting the sidewall of the backside contact DBC and a second flat surface facing away from the sidewall of the backside contact DBC and extends in a direction intersecting the first flat surface. For example, the first flat surface may be a flat/plane surface extending in the first horizontal direction X and the second flat surface may be a flat/plane surface extending in the vertical direction Z. The sidewall GP4S of the gate protective film GP4 opposite the backside contact DBC may recede from the sidewall of the backside contact DBC in a direction moving from the bottom to the top of the sidewall GP4S opposite the backside contact DBC.

FIG. 4E is a diagram illustrating an integrated circuit device 10e according to some embodiments. FIG. 4E shows a portion of the integrated circuit device 10e corresponding to region “EX2” of FIG. 3A. In FIG. 4E, the same reference numerals as those in FIGS. 2 and 3A to 3D are given to the same members, and repeated descriptions thereof are omitted. The integrated circuit device 10e is different from the integrated circuit device 10 described above with reference to FIGS. 2 and 3A to 3D in that the integrated circuit device 10e includes a gate protective film GP5 instead of the gate protective film GP, and thus, the following description focuses on the differences therebetween.

Referring to FIG. 4E, the integrated circuit device 10e may include the gate protective film GP5. A portion of the sidewall of the backside contact DBC may be covered by the gate protective film GP5 and the other portion of the sidewall of the backside contact DBC may be covered by the gap-fill insulating film 192. For example, the gate protective film GP5 may cover/contact the upper sidewall of the backside contact DBC and the gap-fill insulating film 192 may cover/contact the lower sidewall of the backside contact DBC. The gate protective film GP5 may be surrounded by or contact the first source/drain region 130a, the gate dielectric film 152, the gap-fill insulating film 192, and the backside contact DBC.

In some embodiments, the gate protective film GP5 may cover/contact at least a portion of the lower surface of the lowermost end of the gate dielectric film 152. A portion of the lower surface of the gate dielectric film 152 covered by the gate protective film GP5 may be adjacent to the backside contact DBC.

In some embodiments, the backside contact DBC may cover/contact a portion of the lower surface of the first source/drain region 130a and the gate protective film GP5 may cover/contact the other portion of the lower surface of the first source/drain region 130a. For example, the horizontal width of the upper portion of the backside contact DBC in the first horizontal direction X may be less than the horizontal width of the first source/drain region 130a in the first horizontal direction X. In some embodiments, the backside contact DBC may completely cover the lower surface of the first source/drain region 130a and the gate protective film GP5 may not cover (e.g., may not contact) the lower surface of the first source/drain region 130a. For example, the horizontal width of the upper portion of the backside contact DBC in the first horizontal direction X may be equal to or greater than the horizontal width of the first source/drain region 130a in the first horizontal direction X.

The gate protective film GP5 may include or may be a portion of a gap-fill gate protective film GPa (see FIG. 21) remaining after an etching process of forming the backside contact hole BCH (see FIG. 22A). The manufacturing process of the gate protective film GP5 is described below in detail with reference to FIGS. 21 and 22A.

As illustrated in FIG. 4E, the upper surface of the gate protective film GP5 may be covered by or contact the first source/drain region 130a and the gate dielectric film 152, and a sidewall GP5S of the gate protective film GP5 opposite the backside contact DBC may be covered by or contact the gap-fill insulating film 192. In some embodiments, the sidewall GP5S of the gate protective film GP5 opposite the backside contact DBC may have a flat surface. For example, the sidewall/surfaces GP5S of the gate protective film GP5 may include only a plurality of flat surfaces extending in different directions, e.g., in a cross-sectional view. For example, the sidewall/surfaces GP5S of the gate protective film GP5 may include a first flat surface that extends from the sidewall of the backside contact DBC in a direction intersecting the sidewall of the backside contact DBC and a second flat surface facing away from the sidewall of the backside contact DBC and extends in a direction intersecting the first flat surface. For example, the first flat surface may be a flat/plane surface extending diagonally between the first horizontal direction X and the vertical direction Z (e.g., between the first horizontal direction X, the second horizontal direction Y and the vertical direction Z) and the second flat surface may be a flat/plane surface extending in the vertical direction Z. The sidewall GP5S of the gate protective film GP5 opposite the backside contact DBC may recede from the sidewall of the backside contact DBC in a direction moving from the bottom to the top of the sidewall GP5S.

Similar to the integrated circuit device 10 described with reference to FIGS. 2 and 3A to 3D, the integrated circuit devices 10a, 10b, 10c, 10d, and 10e described with reference to FIGS. 4A to 4E include the gate protective films GP1, GP2, GP3, GP4, and GP5. Accordingly, defects in the integrated circuit device due to partial etching of the portion of gate dielectric film 152 adjacent to the backside contact DBC, the source/drain region 130, and the gate line 160 may be prevented from occurring or be reduced during the process of forming the backside contact DBC, thereby obtaining the integrated circuit device having improved reliability.

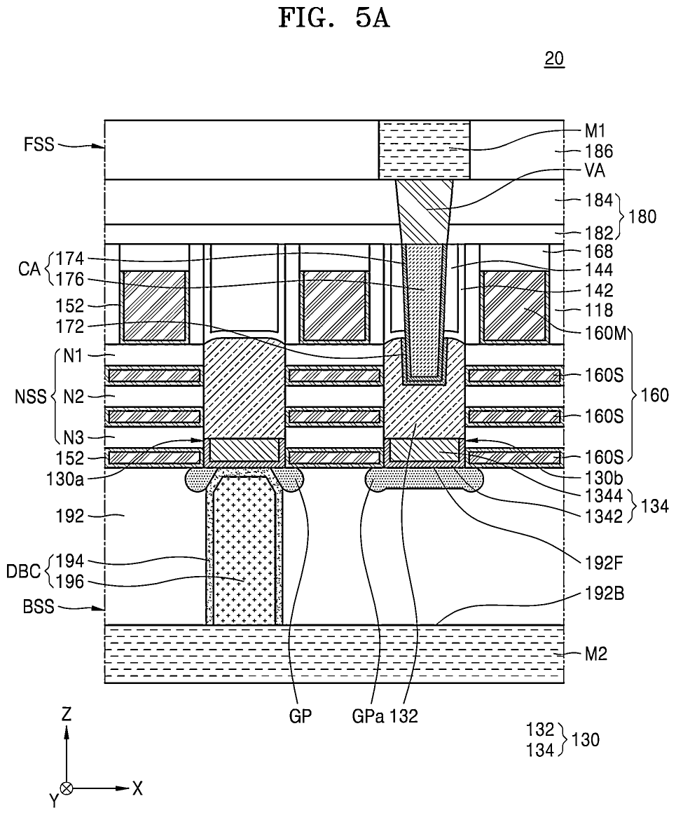

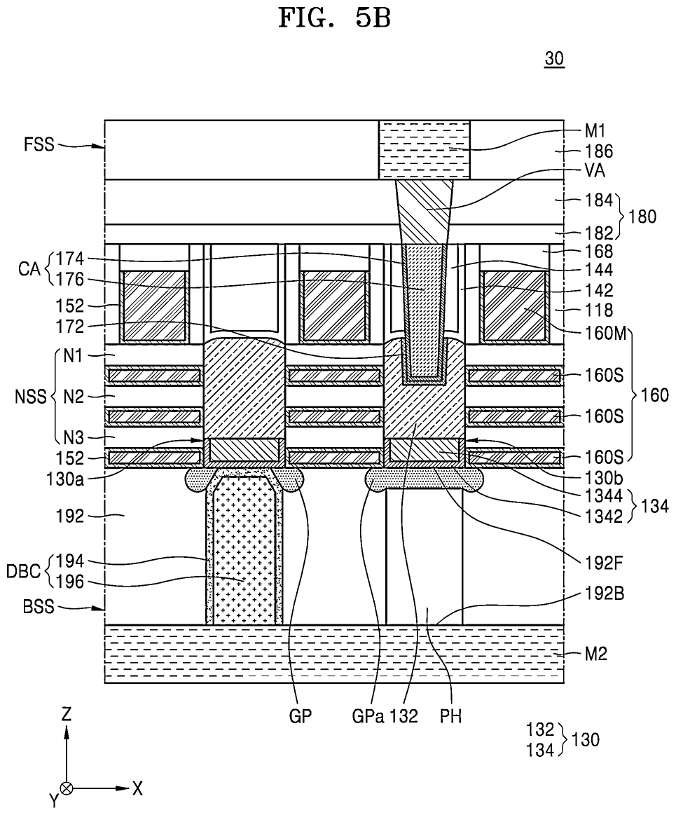

FIG. 5A is a diagram illustrating an integrated circuit device 20 according to some embodiments. FIG. 5A is a cross-sectional view of the integrated circuit device 20, corresponding to the cross-section taken along line X1-X1′ of FIG. 2. In FIG. 5A, the same reference numerals as those in FIGS. 2 and 3A to 3D are given to the same members, and repeated descriptions thereof are omitted. The integrated circuit device 20 is different from the integrated circuit device 10 described above with reference to FIGS. 2 and 3A to 3D in that the integrated circuit device 20 further includes a gap-fill gate protective film GPa, and thus, the following description focuses on the differences therebetween.

As illustrated in FIG. 5A, each of the plurality of source/drain regions 130 may be located between the plurality of nanosheet stacks NSS spaced apart from each other in the first horizontal direction X.

The plurality of gate lines 160 may be disposed above the front surface 192F of the gap-fill insulating film 192. The gap-fill insulating film 192 may cover/contact at least a portion of the lower surface of the lowermost end of the gate dielectric film 152.

In some embodiments, the backside contact DBC may be disposed below a source/drain region 130 selected from among the plurality of source/drain regions 130. For example, the backside contact DBC may be disposed below the first source/drain region 130a. The backside contact DBC may extend, e.g., lengthwise in a vertical direction, through the gap-fill insulating film 192 and come into contact with the source/drain region 130.

In some embodiments, the gate protective film GP may be disposed below the first source/drain region 130a and the gap-fill gate protective film GPa may be disposed below the second source/drain region 130b.

In some embodiments, the gate protective film GP may cover/contact at least a portion of the lower surface of the lowermost end of the gate dielectric film 152. A portion of the lower surface of the gate dielectric film 152 covered by the gate protective film GP may be adjacent to the backside contact DBC.

In some embodiments, the backside contact DBC may cover/contact a portion of the lower surface of the first source/drain region 130a and the gate protective film GP may cover/contact the other portion of the lower surface of the first source/drain region 130a. For example, the horizontal width of the upper portion of the backside contact DBC in the first horizontal direction X may be less than the horizontal width of the first source/drain region 130a in the first horizontal direction X. In some embodiments, the backside contact DBC may completely cover the lower surface of the first source/drain region 130a and the gate protective film GP may not cover (e.g., may not contact) the lower surface of the first source/drain region 130a. For example, the horizontal width of the upper portion of the backside contact DBC in the first horizontal direction X may be equal to or greater than the horizontal width of the first source/drain region 130a in the first horizontal direction X.

In some embodiments, the gap-fill gate protective film GPa may cover/contact at least a portion of the lower surface of the lowermost end of the gate dielectric film 152. A portion of the lower surface of the gate dielectric film 152 covered by the gap-fill gate protective film GPa may be adjacent to the second source/drain region 130b. The horizontal width of the gap-fill gate protective film GPa in the first horizontal direction X may be greater than the horizontal width of the second source/drain region 130b in the first horizontal direction X. In some embodiments, the gap-fill gate protective film GPa may isolate the second source/drain region 130b from the gap-fill insulating film 192. For example, the gap-fill insulating film 192 may be spaced apart from the second source/drain region 130b with the gap-fill gate protective film GPa therebetween.

The gate protective film GP may include or may be a portion of the gap-fill gate protective film GPa remaining after an etching process of forming the backside contact hole BCH (see FIG. 22A). The manufacturing process of the gate protective film GP is described below in detail with reference to FIGS. 21 and 22A.

As illustrated in FIG. 5A, the upper surface of the gate protective film GP may be covered by or contact the first source/drain region 130a and the gate dielectric film 152, and a sidewall of the gate protective film GP opposite the backside contact DBC may be covered by or contact the gap-fill insulating film 192. In some embodiments, the sidewall of the gate protective film GP opposite to the sidewall of the gate protective film GP contacting the backside contact DBC may have a curved shape. The sidewall of the gate protective film GP opposite the backside contact DBC may have a convex shape protruding in a direction receding from the backside contact DBC.

Also, the upper surface of the gap-fill gate protective film GPa may be covered by or contact the second source/drain region 130b and the gate dielectric film 152, and the sidewall and lower surface of the gap-fill gate protective film GPa may be covered by or contact the gap-fill insulating film 192. In some embodiments, the sidewall of the gap-fill gate protective film GPa may have a curved shape. For example, the sidewall of the gap-fill gate protective film GPa may have a convex shape. However, the shape of the gap-fill gate protective film GPa is not limited to that shown in FIG. 5A and may have various shapes. The gap-fill gate protective film GPa may have shapes similar to those of the gate protective film GP1, GP2, GP3, GP4, and GP5 described with reference to FIGS. 4A, 4B, 4C, 4D, and 4E, respectively, thereby the descriptions of the gate protective film GP1, GP2, GP3, GP4, and GP5 may be applied to the gap-fill gate protective film GPa unless the context indicates otherwise.

In some embodiments, the gap-fill gate protective film GPa may include or be formed of SiGe, SiGeC, SiC, SiO, SiOC, SiOCN, SiOH, GeC, or a combination thereof. The gap-fill gate protective film GPa may include or be formed of materials the same as or similar to those described for the constituent materials of the gate protective film GP of FIGS. 3A to 3D. In some embodiments, the gap-fill gate protective film GPa may have a height of about 3 nanometers to about 6 nanometers in the vertical direction Z.

According to embodiments, the gate protective film GP may cover/contact a portion of the lower surface of the gate dielectric film 152 adjacent to the first source/drain region 130a and the gap-fill gate protective film GPa may cover/contact a portion of the lower surface of the gate dielectric film 152 adjacent to the second source/drain region 130b. Accordingly, portions of the gate dielectric film 152 adjacent to the source/drain region 130 are prevented from being etched during the process of forming backside contact DBC, or etching of the gate dielectric film 152 adjacent to the source/drain region 130 may be reduced.

In addition, the gate protective film GP and the backside contact DBC cover/contact the lower surface of the first source/drain region 130a and the gap-fill gate protective film GPa covers/contacts the lower surface of the second source/drain region 130b. Accordingly, the plurality of source/drain regions 130 may be prevented from being etched during the process of forming the backside contact DBC, or etching of the plurality of source/drain regions 130 may be reduced during the process of forming the backside contact DBC. Consequently, defects due to partial etching of the plurality of source/drain regions 130, the gate dielectric film 152, and the plurality of gate lines 160 may be prevented from occurring or be reduced, thereby obtaining the integrated circuit device having improved reliability.

FIG. 5B is a diagram illustrating an integrated circuit device 30 according to some embodiments. FIG. 5B is a cross-sectional view of the integrated circuit device 30, corresponding to the cross-section taken along line X1-XF of FIG. 2. In FIG. 5B, the same reference numerals as those in FIGS. 2, 3A to 3D, and 5A are given to the same members, and repeated descriptions thereof are omitted. The integrated circuit device 30 is different from the integrated circuit device 20 described above with reference to FIG. 5A in that the integrated circuit device 30 further includes a place holder PH, and thus, the following description focuses on the differences therebetween.

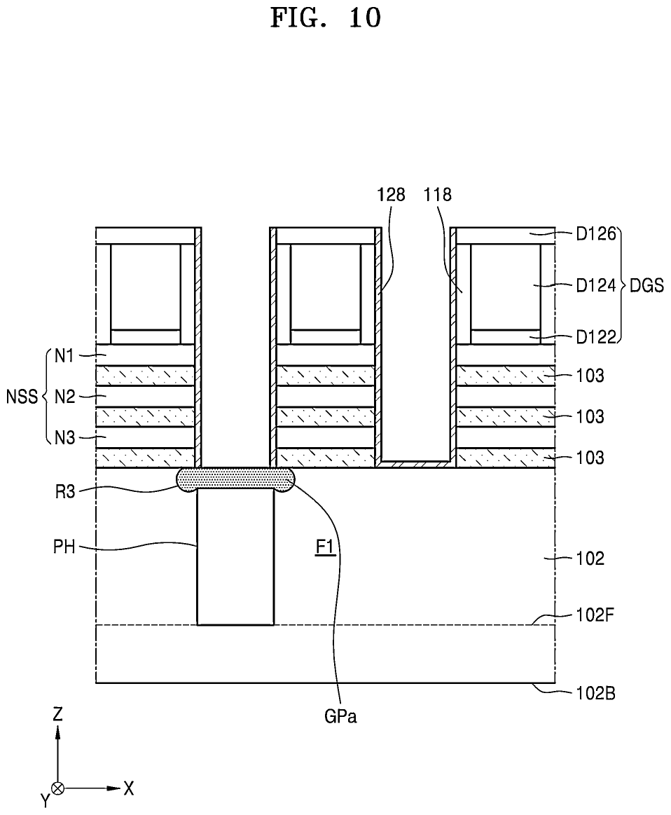

As illustrated in FIG. 5B, the place holder PH formed below the gap-fill gate protective film GPa may extend downwards from the lower surface of the gap-fill gate protective film GPa and pass through the gap-fill insulating film 192. The place holder PH may correspond to a structure formed by the remaining portion of the place holder PH (see FIG. 10) which is formed below the gap-fill gate protective film GPa.

In some embodiments, the place holder PH may include or be formed of a SiGe film. For example, the place holder PH may include or be formed of a single crystalline SiGe film, a polycrystalline SiGe film, an amorphous SiGe film, or a combination thereof.

In some embodiments, the Ge content in the place holder PH may be constant, e.g., throughout the place holder PH. The SiGe film constituting the place holder PH may have a constant Ge content, e.g., throughout the SiGe film, and the Ge content may be selected within a range from about 5 at % to about 60 at %, for example, from about 10 at % to about 40 at %. However, the Ge content in the SiGe film constituting the place holder PH may be selected in various ways within a range in which etch rates of the place holder PH and a fin-type active region F1 (see FIG. 7) are different from each other thereby having a high enough etch selectivity between the place holder PH and the fin-type active region F1.

Next, a method of manufacturing an integrated circuit device, according to embodiments, is described below.

FIGS. 6, 7, 8A, 8B, 9A, 9B, 10, 11A, 11B, 12, 13A, 13B, 14 to 16, 17A, 17B, 18A, 18B, 19A, 19B, 20, 21, 22A, 22B, 23A, and 23B are diagrams illustrating, in a process order, a method of manufacturing an integrated circuit device, according to embodiments.

Specifically, FIGS. 6, 8A, 9A, 10, 11A, 13A, 14 to 16, 17A, 18A, 19A, 20, 21, 22A, and 23A are diagrams showing a manufacturing process corresponding to the cross-section taken along line X1-XF of FIG. 2, and FIGS. 7, 8B, 9B, 11B, 12, 13B, 17B, 18B, 19B, 22B and, 23B are diagrams showing a manufacturing process corresponding to the cross-section taken along line Y1-Y1′ of FIG. 2.

In FIGS. 6, 7, 8A, 8B, 9A, 9B, 10, 11A, 11B, 12, 13A, 13B, 14 to 16, 17A, 17B, 18A, 18B, 19A, 19B, 20, 21, 22A, 22B, 23A, and 23B, the same reference numerals as those in FIGS. 2 and 3A to 3D are given to the same members/elements, and repeated descriptions thereof are omitted herein.

Referring to FIG. 6, a plurality of sacrificial semiconductor layers 103 and a plurality of nanosheet semiconductor layers NS may be alternately stacked one layer at a time on a substrate 102. The substrate 102 may include or be formed of elemental semiconductors, such as Si and Ge, or compound semiconductors, such as SiGe, SiC, GaAs, InAs, InGaAs, and InP. Each of the terms “SiGe,” “SiC,” “GaAs,” “InAs,” “InGaAs,” and “InP” used herein indicates a material including elements shown in each term and is not a chemical formula representing stoichiometric relationships. For example, the substrate 102 may include or may be a bulk Si substrate.

The plurality of sacrificial semiconductor layers 103 and the plurality of nanosheet semiconductor layers NS may include or be formed of semiconductor materials having different etch rates from each other, thereby having a high enough etch selectivity between them. In some embodiments, the plurality of nanosheet semiconductor layers NS may include or may be Si layers and the plurality of sacrificial semiconductor layers 103 may include or may be SiGe film layers. In some embodiments, the Ge contents in the plurality of sacrificial semiconductor layers 103 may be constant, e.g., throughout the plurality of sacrificial semiconductor layers 103. The SiGe film constituting the plurality of sacrificial semiconductor layers 103 may have a constant Ge content, e.g., throughout the SiGe film, and the Ge content may be selected within a range from about 5 at % to about 60 at %, for example, from about 10 at % to about 40 at %. The Ge content in the SiGe film constituting the plurality of sacrificial semiconductor layers 103 may be selected in various ways if necessary.

Referring to FIG. 7, mask patterns MP1 are each formed on the structure illustrated in FIG. 6, and then the plurality of sacrificial semiconductor layers 103, the plurality of nanosheet semiconductor layers NS, and the substrate 102 are partially etched using the mask patterns MP1 as an etch mask. As a result, a fin-type active region F1 may be formed on the substrate 102. A plurality of trench regions T1 may be defined on the substrate 102 by a plurality of fin-type active regions F1. In some embodiments, each mask pattern MP1 may have a stack structure of an oxide film pattern and a silicon nitride film pattern. The mask patterns MP1 may extend parallel to each other in a first horizontal direction X on the substrate 102. A stack structure of the plurality of sacrificial semiconductor layers 103 and the plurality of nanosheet semiconductor layers NS may remain on a fin-top surface FT of each of fin-type active regions F1.

Subsequently, a device isolation insulating film P112 may be formed on the obtained result. The device isolation insulating film P112 may have a thickness sufficient to fill the spaces of the plurality of trench regions T1 above the substrate 102. The device isolation insulating film P112 may include or may be a silicon oxide film.

In order to form the device isolation insulating film P112, a plasma enhanced chemical vapor deposition (PECVD) process, high density plasma CVD (HDP CVD) process, inductively coupled plasma CVD (ICP CVD) process, capacitively coupled plasma CVD (CCP CVD) process, flowable chemical vapor deposition (FCVD) process, spin coating process, etc. may be used.

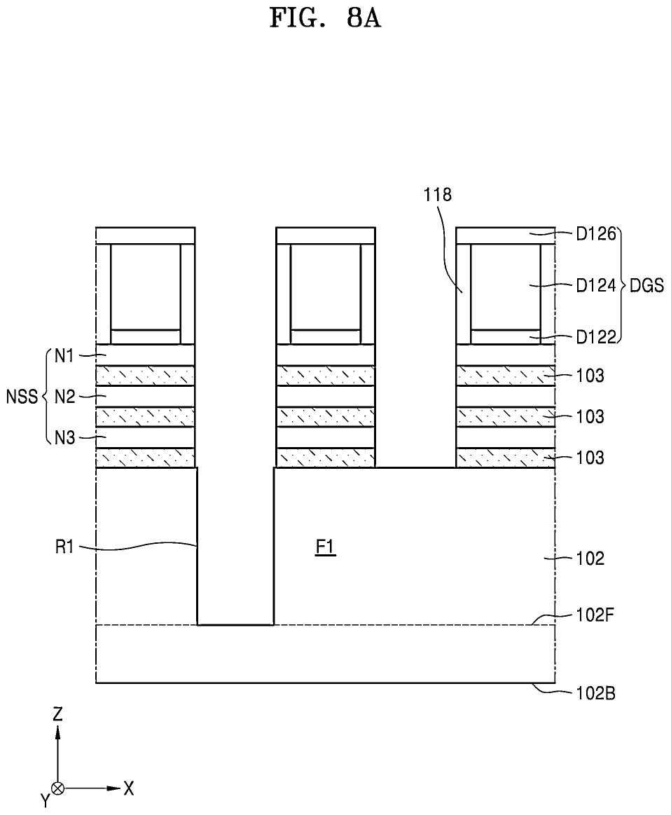

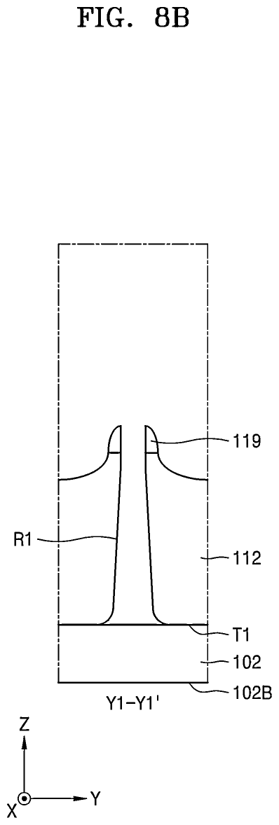

Referring to FIGS. 8A and 8B, after the structure illustrated in FIG. 7 is planarized so that the upper surface of the mask pattern MP1 is exposed, the exposed mask pattern MP1 is removed, and a recess process is performed to remove a portion of the device isolation insulating film P112. Consequently, the device isolation film 112 may be formed. As a result, the plurality of sacrificial semiconductor layers 103 and the plurality of nanosheet semiconductor layers NS (see FIG. 7) may protrude above the upper surface of the device isolation film 112.

In order to perform the recess process of the device isolation insulating film P112, a dry etching process, a wet etching process, or a combination of dry and wet etching processes may be used. Also, wet etching processes using NH₄OH, tetramethyl ammonium hydroxide (TMAH), potassium hydroxide (KOH), or the like as an etchant may be used. In addition, dry etching processes, such as inductively coupled plasma (ICP), transformer coupled plasma (TCP), electron cyclotron resonance (ECR), and/or reactive ion etch (RIE) may be used. When the recess process for the device isolation insulating film P112 is performed by using the dry etching process, a fluorine-containing gas, such as CF₄, a chlorine-containing gas, such as Cl₂, HBr, or the like may be used as an etching gas.

A plurality of dummy gate structures DGS may be formed on the stack structure of the plurality of sacrificial semiconductor layers 103 and the plurality of nanosheet semiconductor layers NS. Each of the plurality of dummy gate structures DGS may extend lengthwise in a second horizontal direction Y. Each of the plurality of dummy gate structures DGS may have a structure in which an oxide film D122, a dummy gate layer D124, and a capping layer D126 are sequentially stacked on a top surface of the stack structure of the plurality of sacrificial semiconductor layers 103 and the plurality of nanosheet semiconductor layers NS. In some embodiments, the oxide film D122 may include or may be a film that is obtained by oxidizing the surface of an uppermost one of the plurality of nanosheet semiconductor layers NS (see FIG. 7). The dummy gate layer D124 may include or be formed of polysilicon and the capping layer D126 may include or may be a silicon nitride film.

The plurality of outer insulating spacers 118 are formed covering both sidewalls of each of the plurality of dummy gate structures DGS, and then each of the plurality of sacrificial semiconductor layers 103 and the plurality of nanosheet semiconductor layers NS is partially etched using the plurality of dummy gate structures DGS and the plurality of outer insulating spacers 118 as an etch mask. Accordingly, the plurality of nanosheet semiconductor layers NS are divided into a plurality of nanosheet stacks NSS each including a first nanosheet N1, a second nanosheet N2, and a third nanosheet N3. In order to etch a portion of each of the plurality of sacrificial semiconductor layers 103 and the plurality of nanosheet semiconductor layers NS, dry etching, wet etching, or a combination thereof may be used.

Subsequently, a first recess R1 may be formed by partially etching the fin-type active region F1 which is exposed by partially etching the plurality of sacrificial semiconductor layers 103 and the plurality of nanosheet semiconductor layers NS. In order to form the first recess R1, an etching process may be performed using dry etching, wet etching, or a combination thereof. After the first recess R1 is formed, a plurality of recess-side insulating spacers 119 adjacent to the first recess R1 may be formed on the device isolation film 112.

In some embodiments, an etching process may be performed to form the first recess R1 so that the bottom of the first recess R1 is at the same level in the vertical direction Z as the bottom surface of the trench region T1 defining the fin-type active region F1. However, the embodiment is not limited thereto. The bottom of the first recess R1 may be at a level higher than that of the bottom surface of the trench region T1 defining the fin-type active region F1 or at a level lower than that of the bottom surface of the trench region T1 defining the fin-type active region F1.

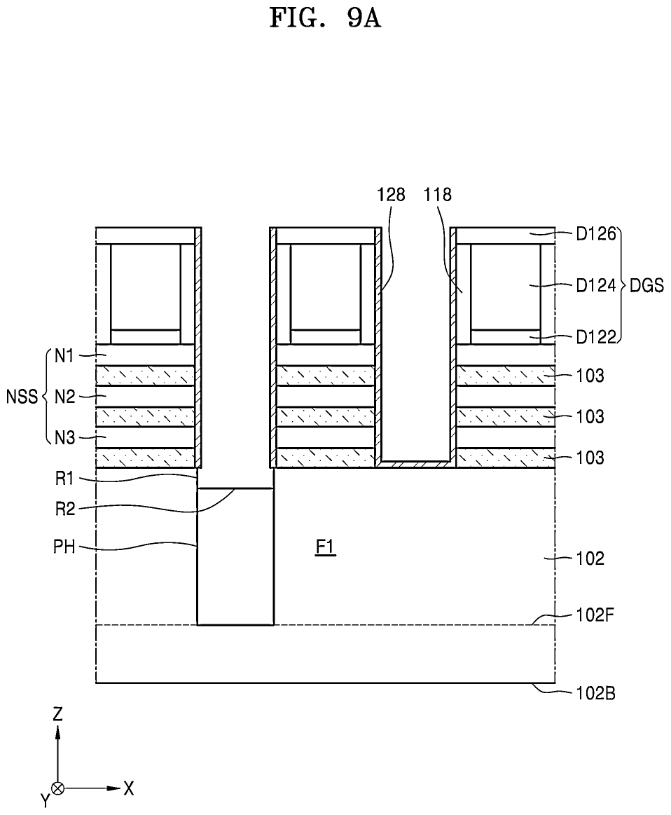

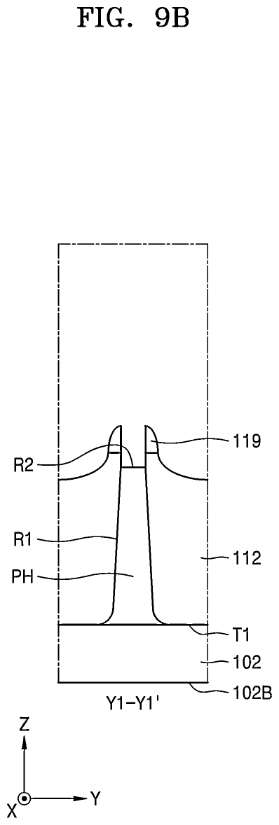

Referring to FIGS. 9A and 9B, a sacrificial insulating spacer 128 may be formed, extending along the sidewall of the capping layer D126, the sidewalls of the plurality of outer insulating spacers 118, and the sidewalls of the plurality of nanosheet stacks NSS. The sacrificial insulating spacer 128 may extend to cover the upper surface of the fin-type active region F1 that is exposed in the structure illustrated in FIGS. 8A and 8B.

For example, the sacrificial insulating spacer 128 may include or be formed of a silicon nitride film. The sacrificial insulating spacer 128 may be deposited using various methods, such as a PECVD, HDP CVD, ICP CVD, CCP CVD, FCVD, and spin coating process.

Subsequently, a portion of the sacrificial insulating spacer 128 extending along the inner wall of the first recess R1 may be removed, and a place holder PH filling the first recess R1 may be formed. In some embodiments, the place holder PH may include or be formed of a SiGe film. For example, the place holder PH may include or be formed of a single crystalline SiGe film, a polycrystalline SiGe film, an amorphous SiGe film, or a combination thereof.

In some embodiments, the place holder PH may be deposited by various methods, such as a PECVD, HDP CVD, ICP CVD, CCP CVD, and FCVD process, using raw materials containing element precursors. In some embodiments, in order to form the place holder PH, an low pressure CVD (LPCVD), selective epitaxial growth (SEG), or cyclic deposition etch (CDE) process may be performed using raw materials that include element semiconductor precursors. The element semiconductor precursor may include or may be a Si source containing the element Si. Silane (SiH₄), disilane (Si₂H₆), trisilane (Si₃H₈), dichlorosilane (SiH₂Cl₂), or the like may be used as the Si source, but the inventive concept is not limited thereto. Also, the element semiconductor precursor may include or may be a Ge source containing the element Ge. Germane (GeH₄), digermane (Ge₂H₆), trigermane (Ge₃H₈), tetragermane (Ge₄H₁₀), dichlorgermane (GeH₂Cl₂), or the like may be used as the Ge source, but the inventive concept is not limited thereto. For example, the place holder PH may be formed by epitaxially growing a SiGe film from the surface of the fin-type active region F1 that is exposed from the sidewall and bottom of the first recess R1. In this case, the place holder PH may include or may be a single crystalline SiGe film.

In some embodiments, the Ge content in the place holder PH may be constant, e.g., throughout the place holder PH. The SiGe film constituting the place holder PH may have a constant Ge content, e.g., throughout the SiGe film, and the Ge content may be selected within a range from about 5 at % to about 60 at %, for example, from about 10 at % to about 40 at %. However, the Ge content in the SiGe film constituting the place holder PH may be selected in various ways within a range in which etch rates of the place holder PH and a fin-type active region F1 are different from each other, thereby having a high enough etch selectivity between the place holder PH and a fin-type active region F1.

In some embodiments, a plurality of first recesses R1 may be provided and a plurality of place holders PH filling the plurality of first recesses R1 may also be provided.

Subsequently, the upper portion of the place holder PH may be partially and selectively etched to form a second recess R2. The selective etching process of partially and selectively etching the upper portion of the place holder PH may be performed using a dry etching process, a wet etching process, or a combination thereof. The selective etching process may utilize a feature in which the place holder PH has a higher etch rate than (e.g., a high etch selectivity to) the fin-type active region F1. For example, in order to remove the place holder PH, a wet etching process may be performed using an etchant in which HF, H₂O₂, and CH₃COOH are mixed.

In some embodiments, the second recess R2 may have a height of 3 nanometers to about 6 nanometers from the upper surface of the place holder PH to the upper surface of the fin-type active region F1 in the vertical direction Z.

Referring to FIG. 10, a third recess R3 may be formed by partially recessing the fin-type active region F1 which is exposed on the sidewall of the second recess R2. In order to form the third recess R3, a dry etching process, a wet etching process, or a combination thereof may be used. The etching process of forming the third recess R3 may be performed in-situ with the etching process of forming the second recess R2 described with reference to FIGS. 9A and 9B. The etching process of forming the third recess R3 may utilize a feature in which the fin-type active region F1 has a higher etch rate than (e.g., a high etch selectivity to) the place holder PH.

In some embodiments, in order to form the gate protective films GP and GP1 having curved shapes as shown in FIGS. 3D and 4A, respectively, the third recess R3 may be formed using an isotropic etching process. For example, the etching process may be performed using HCl, or the etching process may be performed using reactive ion etching (RIE).

In some embodiments, in order to form the gate protective films GP2, GP3, GP4, and GP5 having a pointy or angular shape as shown in FIGS. 4B, 4C, 4D, and 4E, respectively, the third recess R3 may be formed using an anisotropic etching process. For example, when the etching process is performed using KOH, NHOH₄, or tetramethylammonium hydroxide (TMAH), the etching rate on a crystal plane (lattice plane) in a specific direction is different from the etching rate on a crystal plane (lattice plane) in another direction, and thus, the third recess R3 may be formed having a pointy or angular shape.

Subsequently, a gap-fill gate protective film GPa may be formed to fill the third recess R3. The gap-fill gate protective film GPa may include a material having an etch rate different from that of the fin-type active region F1, e.g., to have a high enough etch selectivity to the fin-type active region F1. For example, the gap-fill gate protective film GPa may include or be formed of a material that has a higher bonding energy than a material constituting the fin-type active region F1. The gap-fill gate protective film GPa may include or be formed of a silicon oxide film, silicon carbide film, SiOC, SiOCN, SiOH, GeC, or a combination thereof. The gap-fill gate protective film GPa may include or be formed of a single crystalline, polycrystalline, or amorphous film. For example, the gap-fill gate protective film GPa may include or may be a silicon carbide film, and the carbon content in the gap-fill gate protective film GPa may be about 10 at % to about 30 at % or about 5 at % to about 25 at %.

In some embodiments, the gap-fill gate protective film GPa may be deposited by various methods, such as a PECVD, HDP CVD, ICP CVD, CCP CVD, and FCVD process, using raw materials containing element precursors. In some embodiments, in order to form the gap-fill gate protective film GPa, an LPCVD, SEG, or CDE process may be performed using raw materials that include element semiconductor precursors. The element precursor may include or may be a Si source containing the element Si, a C source containing the element C, an N source containing the element N, an N source containing OH, or a Ge source containing the element Ge. For example, the gap-fill gate protective film GPa may be formed by epitaxially growing a silicon carbide film from the surface of the fin-type active region F1 exposed from a portion of the inner wall of the third recess R3 and the surface of the place holder PH exposed from the other portion of the inner wall of the third recess R3.

In some embodiments, when the plurality of place holders PH is provided in the integrated circuit device, a plurality of gap-fill gate protective films GPa may also be provided in the integrated circuit device.

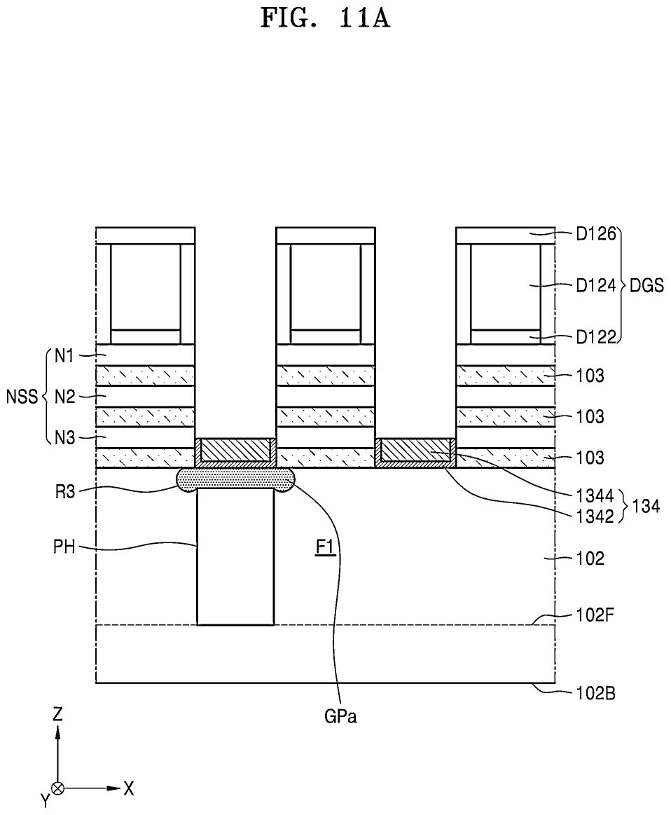

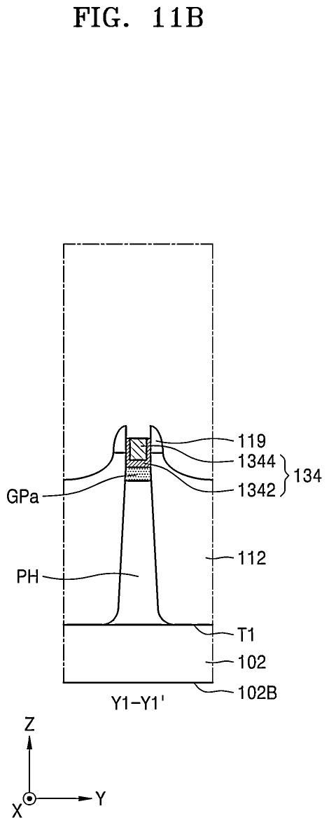

Referring to FIGS. 11A and 11B, a plurality of lower source/drain regions 134 may be formed after selectively removing the sacrificial insulating spacer 128. A liquid or vapor phase etchant may be used to selectively remove the sacrificial insulating spacer 128. In some embodiments, a CH₃COOH-based etchant, for example, an etchant including a mixture of CH₃COOH, HNO₃, and HF or an etchant including a mixture of CH₃COOH, H₂O₂, and HF may be used to selectively remove the sacrificial insulating spacer 128, but the inventive concept is not limited to these examples.

Each of the plurality of lower source/drain regions 134 may include or be formed of a first semiconductor film 1342 and a second semiconductor film 1344. Each of the first semiconductor film 1342 and the second semiconductor film 1344 may include or may be a single crystalline, polycrystalline, or amorphous film. Each of the first semiconductor film 1342 and the second semiconductor film 1344 may include or may be a Si film or SiGe film. In some embodiments, the first semiconductor film 1342 may include or may be a Si film and the second semiconductor film 1344 may include or may be a SiGe film. Also, in some embodiments, when each of the first semiconductor film 1342 and the second semiconductor film 1344 includes a SiGe film, the Ge content in the first semiconductor film 1342 may be less than the Ge content in the second semiconductor film 1344.

The first semiconductor film 1342 and the second semiconductor film 1344 may be sequentially deposited by various methods, such as a PECVD, HDP CVD, ICP CVD, CCP CVD, and FCVD process, using raw materials containing element precursors. For example, the first semiconductor film 1342 may be formed by epitaxially growing a Si film or SiGe film from the surface of the fin-type active region F1, the surface of the gap-fill gate protective films GPa, and the sidewall of the nanosheet stack NSS. Also, the second semiconductor film 1344 may be formed by epitaxially growing a SiGe film from the surface of the first semiconductor film 1342 and the sidewall of the nanosheet stack NSS.

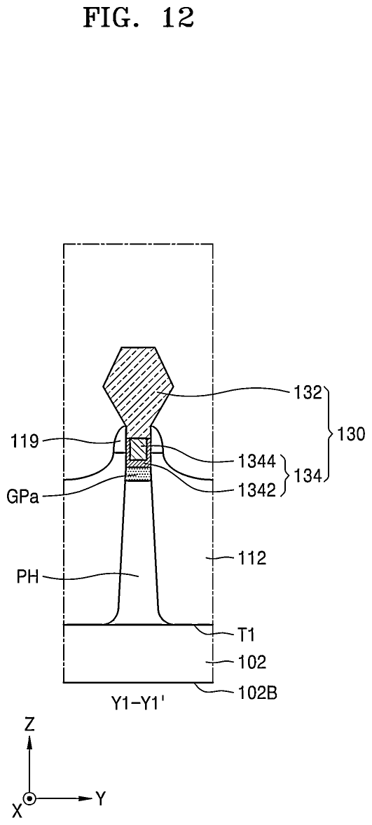

Referring to FIG. 12, a plurality of upper source/drain regions 132 may be formed on the structure illustrated in FIGS. 11A and 11B, thereby forming a plurality of source/drain regions 130. The plurality of source/drain regions 130 may include a first source/drain region 130a and a second source/drain region 130b.

In order to form the plurality of upper source/drain regions 132, semiconductor materials may be grown epitaxially from the surfaces of the plurality of lower source/drain regions 134 exposed in the structure illustrated in FIGS. 11A and 11B and the sidewall of each of the first nanosheet N1, the second nanosheet N2, and the third nanosheet N3 in the nanosheet stack NSS.

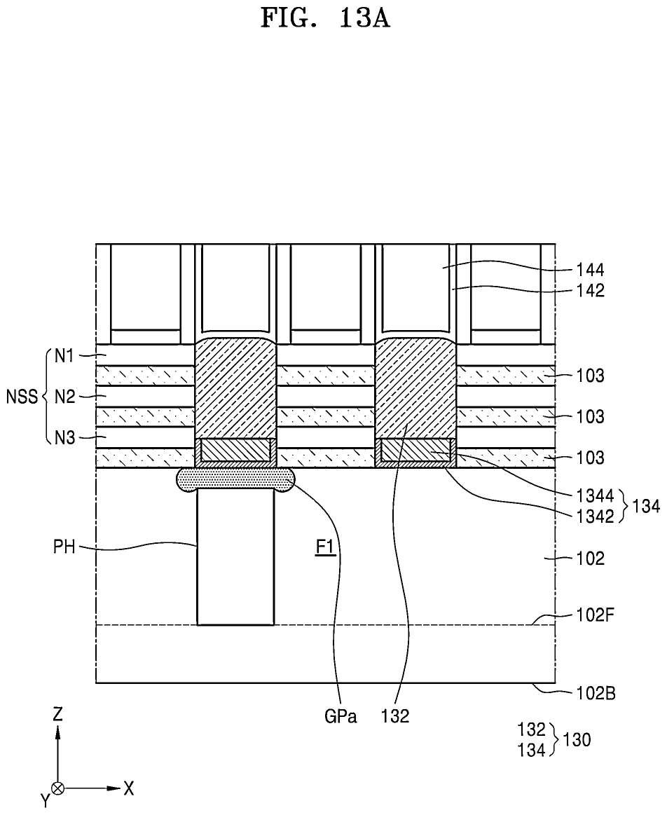

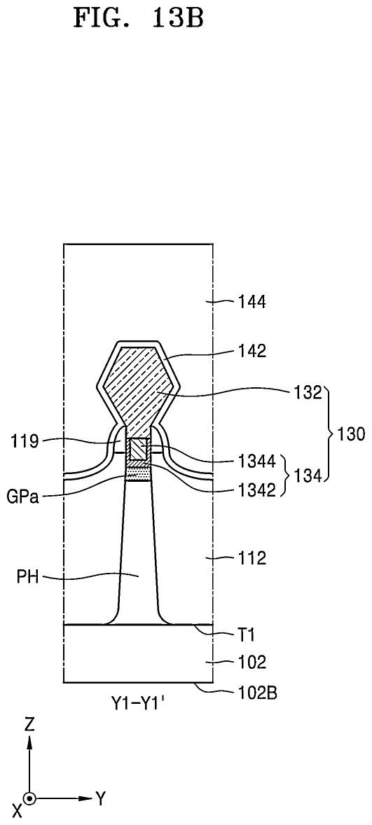

Referring to FIGS. 13A and 13B, an insulating liner 142 is formed covering the structure illustrated in FIG. 12, and an inter-gate insulating film 144 is formed on the insulating liner 142. Subsequently, a portion of each of the insulating liner 142 and the inter-gate insulating film 144 may be etched to expose the upper surfaces of the plurality of capping layers D126. Then, the plurality of capping layers D126 are removed to expose the dummy gate layer D124, and the insulating liner 142 and the inter-gate insulating film 144 may be partially removed so that the upper surface of the inter-gate insulating film 144 and the upper surface of the dummy gate layer D124 are at approximately the same level.

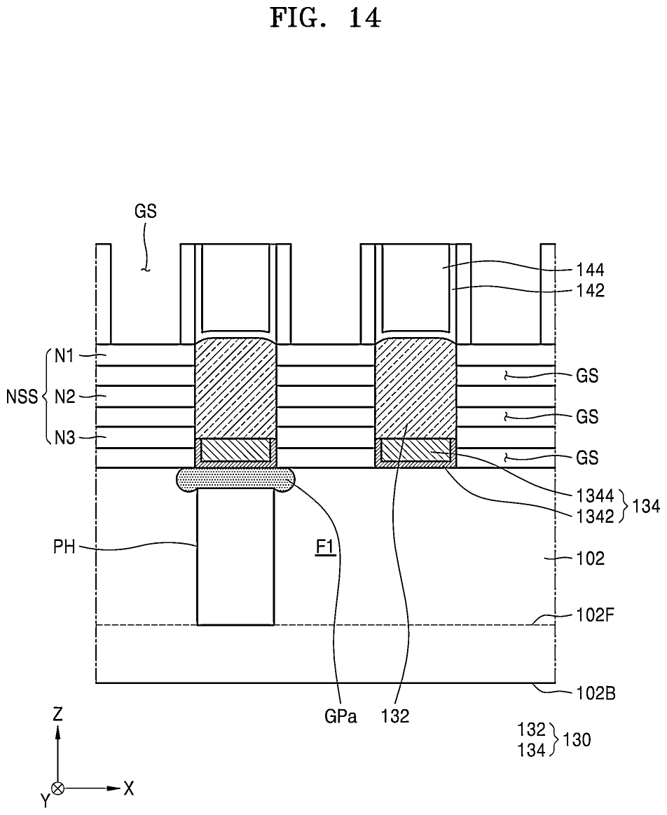

Referring to FIG. 14, a gate space GS may be prepared by removing the dummy gate layer D124 and the oxide film D122 below the dummy gate layer D124 from the structure illustrated in FIGS. 13A and 13B, and the plurality of nanosheet stacks NSS may be exposed through the gate space GS. Subsequently, the plurality of sacrificial semiconductor layers 103 may be removed through the gate space GS, and thus, the gate space GS may be expanded to each of spaces between the first nanosheet N1, the second nanosheet N2, and the third nanosheet N3 and a space between the third nanosheet N3 and the upper surface of the fin-type active region F1. In some embodiments, in order to selectively remove the plurality of sacrificial semiconductor layers 103, a feature in which the first nanosheet N1, the second nanosheet N2, and the third nanosheet N3 have an etch rate different from that of the plurality of sacrificial semiconductor layers 103, e.g., to have a high etch selectivity to the plurality of sacrificial semiconductor layers 103, may be used.

A liquid or vapor phase etchant may be used to selectively remove the plurality of sacrificial semiconductor layers 103. In some embodiments, a CH₃COOH-based etchant, for example, an etchant including or formed of a mixture of CH₃COOH, HNO₃, and HF or an etchant including or formed of a mixture of CH₃COOH, H₂O₂, and HF may be used to selectively remove the plurality of sacrificial semiconductor layers 103, but the inventive concept is not limited to these examples.

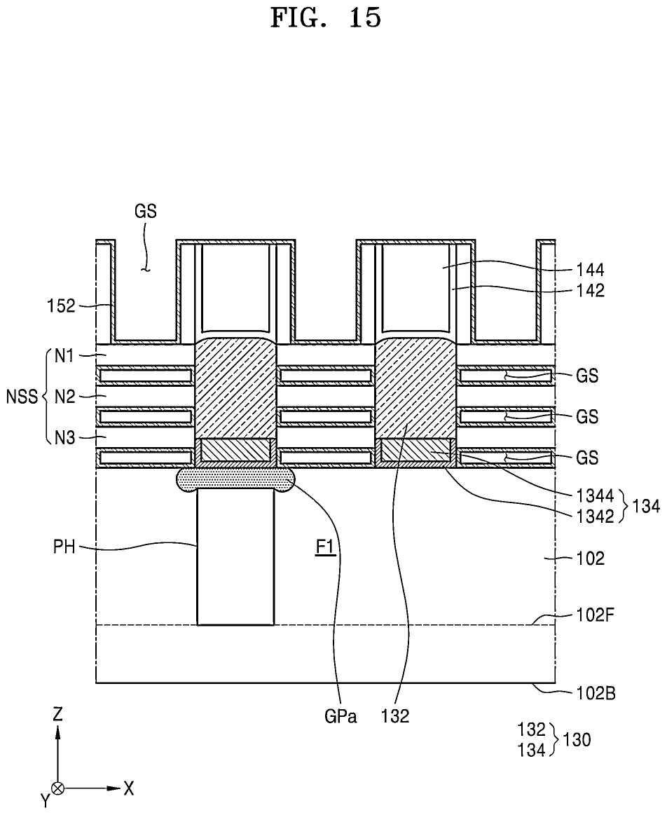

Referring to FIG. 15, a gate dielectric film 152 covering the exposed surfaces of each of the first nanosheet N1, the second nanosheet N2, the third nanosheet N3, and the fin-type active region F1 may be formed on the structure illustrated in FIG. 14. An atomic layer deposition (ALD) process may be used to form the gate dielectric film 152.

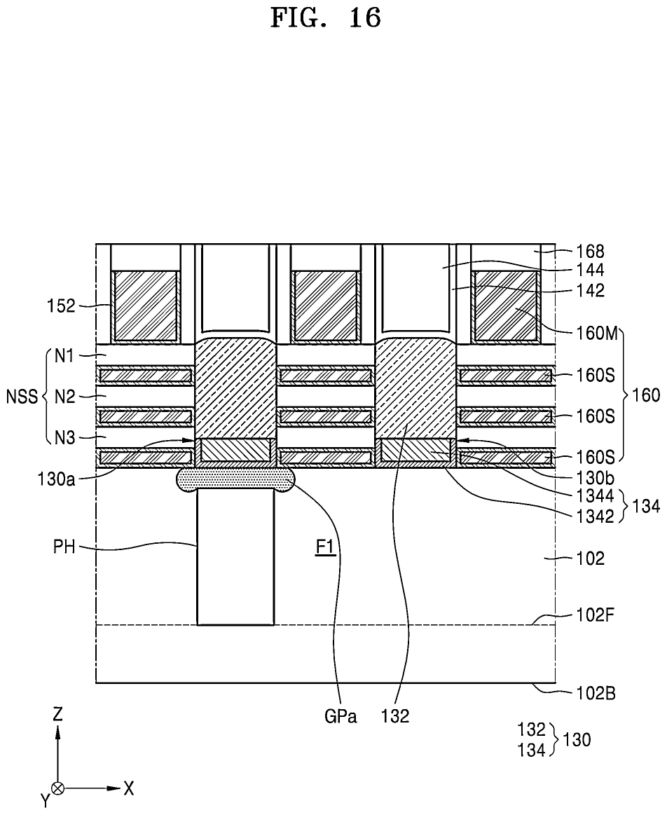

Referring to FIG. 16, a gate line 160 may be formed to fill the gate space GS (see FIG. 15) from above the gate dielectric film 152 and cover the upper surface of the inter-gate insulating film 144. A capping insulating pattern 168 may be formed to cover the upper surface of each of the gate line 160 and the gate dielectric film 152 in the gate space GS.

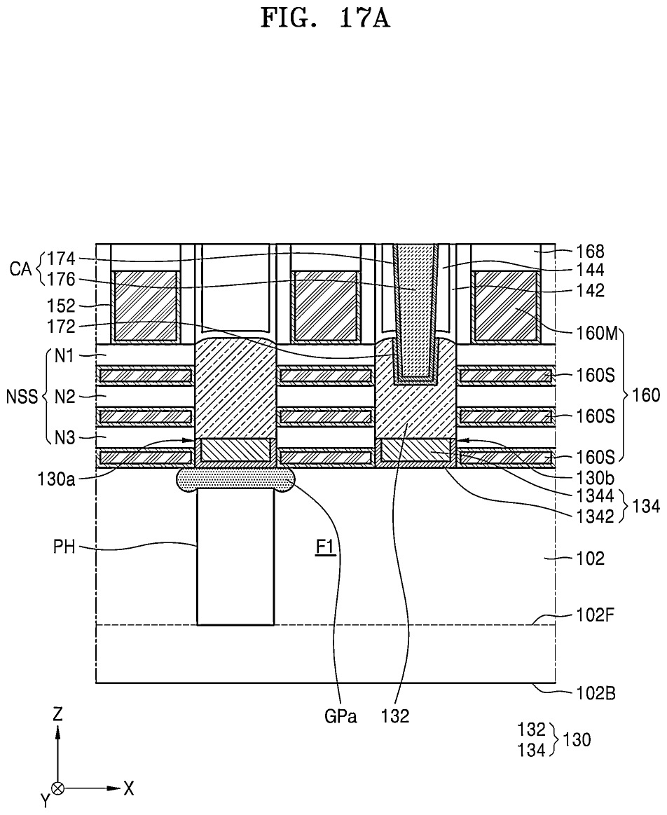

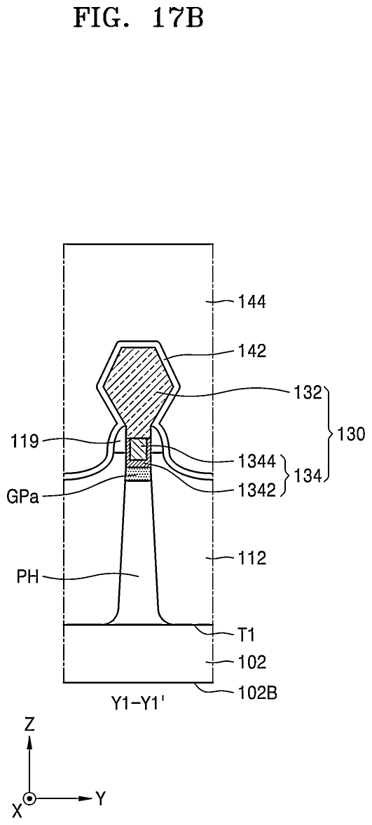

Referring to FIGS. 17A and 17B, a source/drain contact hole (not shown) is formed in the structure illustrated in FIG. 16 so as to pass through the insulating structure including the insulating liner 142 and the inter-gate insulating film 144 and expose the second source/drain region 130b. A portion of the second source/drain region 130b is removed by an anisotropic etching process through the source/drain contact hole. Accordingly, the source/drain contact hole may extend long in the vertical direction Z. Subsequently, a metal silicide film 172 may be formed on the second source/drain region 130b exposed on the bottom and side of the source/drain contact hole. In some embodiments, in order to form the metal silicide film 172, a metal liner (not shown) is formed to conformally cover the exposed surface of the second source/drain region 130b and then heat-treated. Also, a process may be performed to induce a reaction between the second source/drain region 130b and the metal constituting the metal liner. After the metal silicide film 172 is formed, the remaining portion of the metal liner may be removed. During the process of forming the metal silicide film 172, a portion of the second source/drain region 130b may be consumed. In some embodiments, when the metal silicide film 172 includes or is a titanium silicide film, the metal liner may include or may be a Ti film.

Subsequently, a source/drain contact CA including a conductive barrier pattern 174 and a contact plug 176 may be formed on the metal silicide film 172.

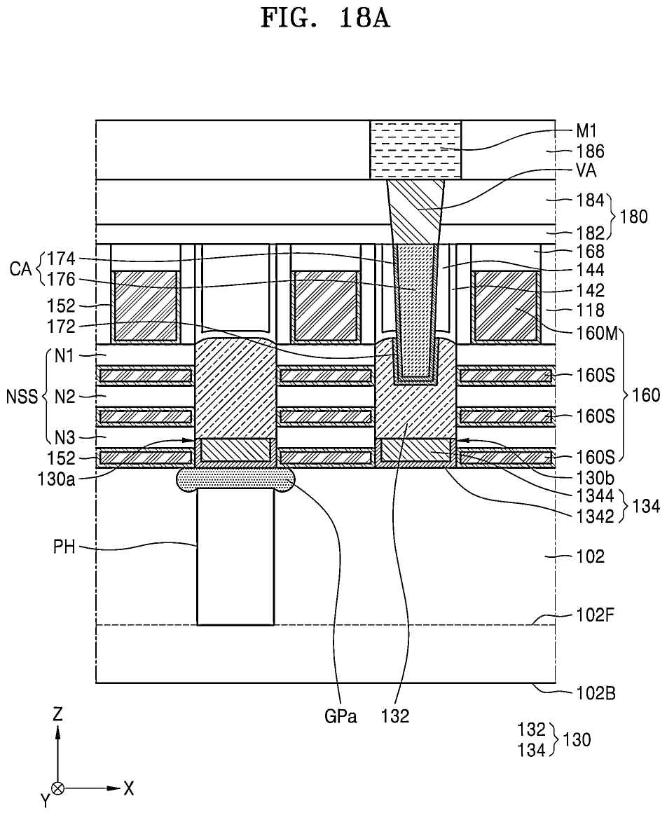

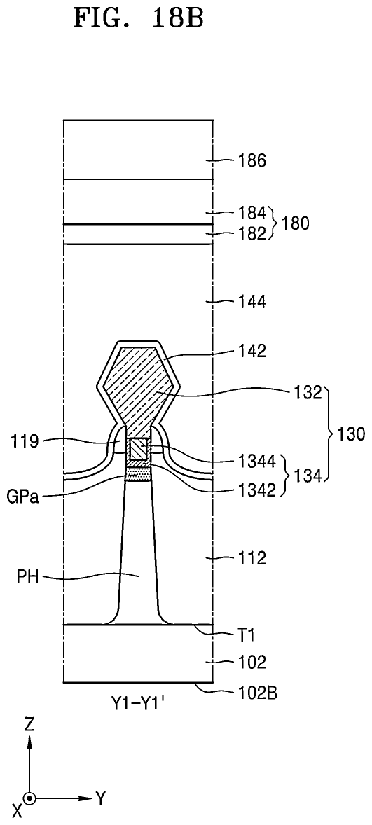

Referring to FIGS. 18A and 18B, an etch stop film 182 and an interlayer insulating film 184 may be sequentially formed on the structure illustrated in FIGS. 17A and 17B so as to cover the upper surface of each of the inter-gate insulating film 144, the source/drain contact CA, and the plurality of capping insulating patterns 168, thereby forming an upper insulating structure 180. Subsequently, a source/drain via contact VA may be formed so as to pass through the upper insulating structure 180 in the vertical direction Z and electrically connected to or contact the source/drain contact CA.

Subsequently, an upper insulating film 186 may be formed to cover the upper insulating structure 180, and an upper wiring layer M1 may be formed through the upper insulating film 186 and electrically connected to or contact the source/drain via contact VA.

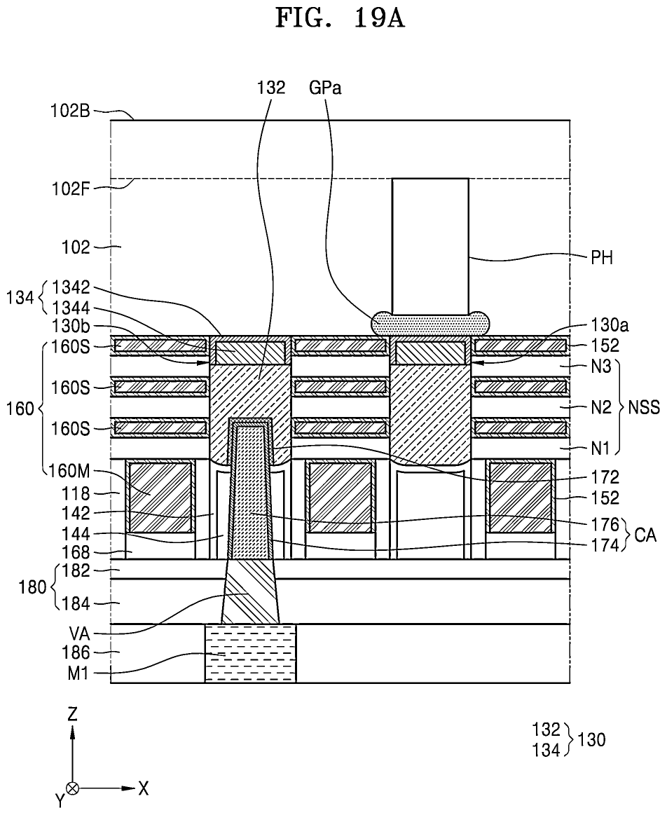

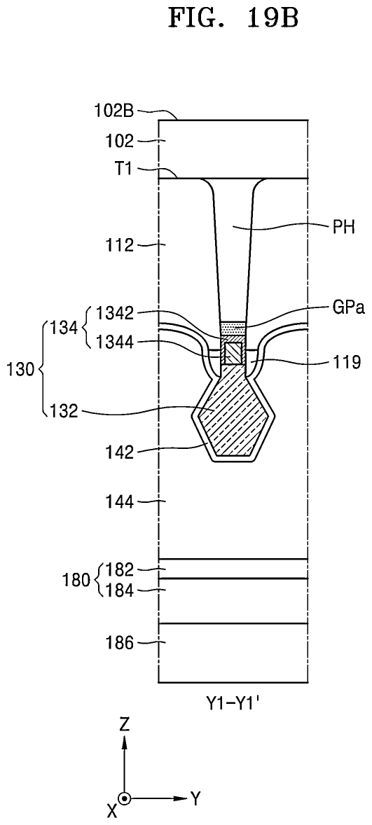

Referring to FIGS. 19A and 19B, the structure illustrated in FIGS. 18A and 18B may be arranged such that a rear surface 102B of the substrate 102 faces upward and a front surface 102F of the substrate 102 faces downward. Subsequently, a chemical mechanical polishing process may be performed on the rear surface 102B of the substrate 102 to expose the place holder PH.

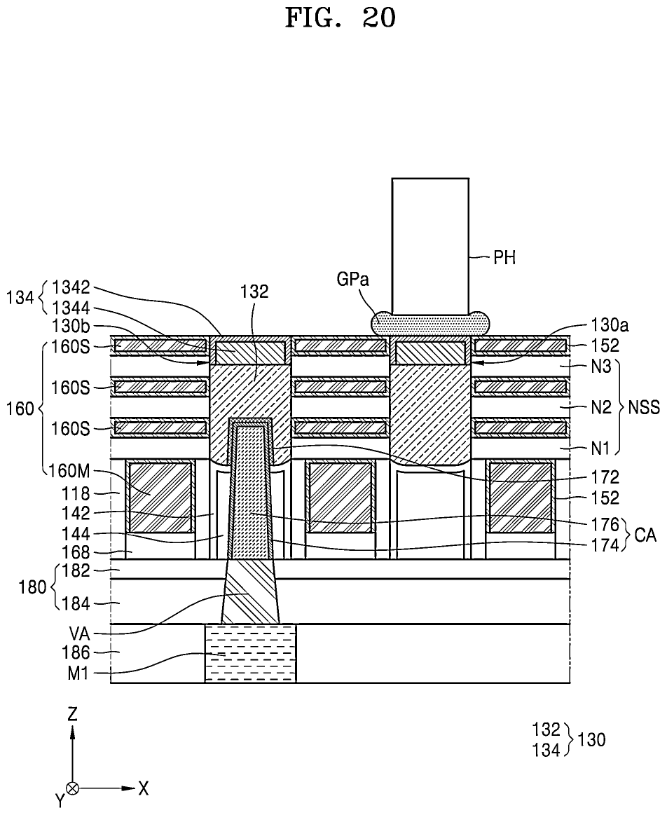

Referring to FIG. 20, the fin-type active region F1 surrounding the place holder PH of FIGS. 19A and 19B may be selectively removed. In order to selectively remove the fin-type active region F1 surrounding the place holder PH, a feature in which the gap-fill gate protective film GPa, the place holder PH, and the gate dielectric film 152 have etch rates different from that of the fin-type active region F1, e.g., to have high etch selectivities to the fin-type active region F1, may be used. For example, to selectively remove the fin-type active region F1 surrounding the exposed place holder PH, a RIE process, a thermal etching process, or a wet etching process using a liquid or vapor phase etchant may be performed. For example, an etchant including TMAH may be used, but the inventive concept is not limited thereto.

Also, the gap-fill gate protective film GPa may include a material not only having a higher bonding energy than the material constituting the fin-type active region F1 but also having a higher bonding energy than the material constituting the place holder PH or the first source/drain region 130a (e.g., the first semiconductor film 1342 of the first source/drain region 130a). Accordingly, during the selective removal process of the fin-type active region F1, the gap-fill gate protective film GPa may not be removed together.

For example, when the substrate 102 includes or is formed of Si, the place holder PH or the first source/drain region 130a (e.g., the first semiconductor film 1342 of the first source/drain region 130a) includes or is formed of SiGe, and the gap-fill gate protective film GPa includes or is formed of a silicon carbide film, the bonding energy between Si and C constituting the gap-fill gate protective film GPa may be greater than the bonding energy between Si and Si constituting the substrate 102 and the bonding energy between Si and Ge constituting the place holder PH or the first source/drain region 130a. Therefore, the gap-fill gate protective film GPa may prevent defects from occurring in the gate line 160 due to partial etching of the first source/drain region 130a during the selective removal process of the fin-type active region F1.

Referring to FIG. 21, a gap-fill insulating film 192 may be formed in a space formed by selectively removing the fin-type active region F1 (see FIG. 19A) to surround the exposed place holder PH. In order to form the gap-fill insulating film 192, various methods, such as a PVD, CVD, or ALD process, may be used.

Subsequently, a chemical mechanical polishing process may be performed on the upper surface of the gap-fill insulating film 192 so as to planarize the upper surface of the gap-fill insulating film 192.

Referring to FIGS. 22A and 22B, an etching process may be performed to remove the place holder PH to form a backside contact hole BCH in the structure illustrated in FIG. 21. The etching process of removing the place holder PH may include a selective etching process that utilizes a feature in which the place holder PH includes a material different from that of the gap-fill insulating film 192. For example, RIE may be performed to remove the place holder PH. The gap-fill gate protective film GPa (see FIG. 21) may be exposed by removing the place holder PH.

Subsequently, the central region of the gap-fill gate protective film GPa may be partially removed. In some embodiments, RIE may be performed to remove the central region of the gap-fill gate protective film GPa. A fourth recess R4 may be formed by removing the place holder PH and the central region of the gap-fill gate protective film GPa, and the first source/drain region 130a may be exposed through the bottom surface of the fourth recess R4. After the central region of the gap-fill gate protective film GPa is removed, a gate protective film GP including or formed of the remaining gap-fill gate protective film GPa may be formed.

In some embodiments, in the case where there are a plurality of place holders PH and a plurality of gap-fill gate protective films GPa, an etching process is performed on the plurality of place holders PH, and then, RIE is performed on the gap-fill gate protective film GPa covering the first source/drain region 130a. However, in order to leave the gap-fill gate protective film GPa covering the second source/drain region 130b, the RIE may be performed using a mask (not shown) that exposes the gap-fill gate protective film GPa covering the first source/drain region 130a. As a result, a structure including the gap-fill gate protective films GPa of FIG. 5A may be formed. For example, the mask may fill the space from which the place holders PH on the gap-fill gate protective film GPa covering the second source/drain region 130b are removed. In certain embodiments, another layer may fill the space from which the place holders PH on the gap-fill gate protective film GPa covering the second source/drain region 130b are removed after the mask is removed.

In some embodiments, in the case where there are a plurality of place holders PH and a plurality of gap-fill gate protective films GPa, when an etching process is performed on the plurality of the place holders PH, an etching process is performed on the place holder PH on the first source/drain region 130a. However, in order to leave the place holder PH on the second source/drain region 130b, the etching process may be performed using a mask (not shown) that exposes the place holder PH on the first source/drain region 130a. As a result, a structure including the place holder PH and the gap-fill gate protective films GPa of FIG. 5B may be formed.

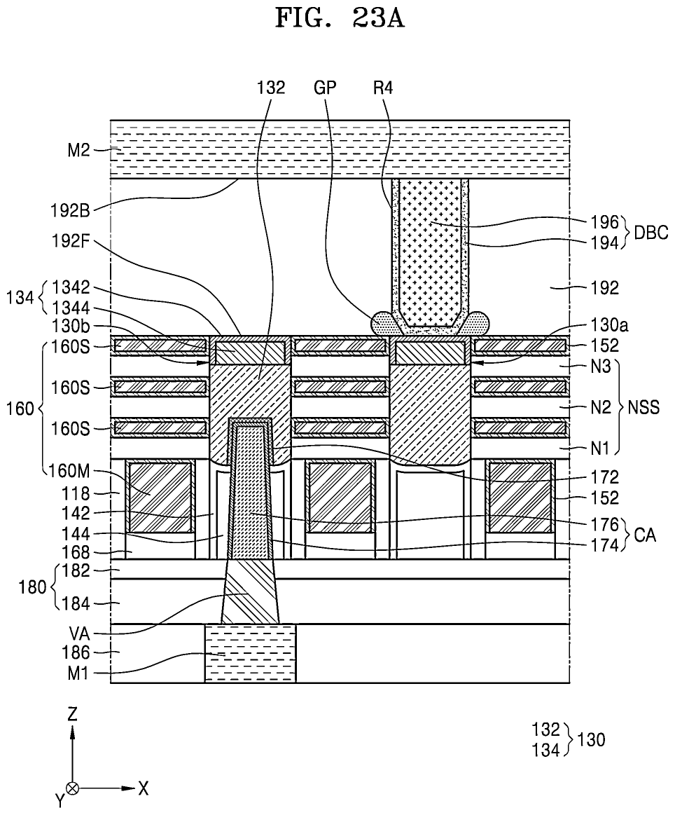

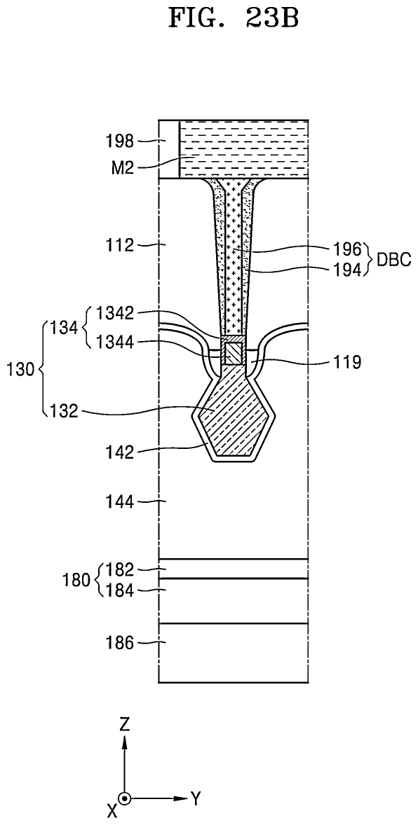

Referring to FIGS. 23A and 23B, the backside contact DBC may be formed inside the fourth recess R4. The backside contact DBC may include a backside barrier film 194 and a backside via 196. The backside barrier film 194 may be formed to conformally extend along the inner wall of the fourth recess R4, and then, the backside via 196 may be formed on the backside barrier film 194. The backside barrier film 194 and the backside via 196 may be deposited using CVD or ALD and/or may be deposited using various processes.

In some embodiments, although not shown in the drawings, a metal silicide film may be formed on the first source/drain region 130a exposed by the fourth recess R4. In some embodiments, in order to form the metal silicide film, a metal liner (not shown) is formed to conformally cover the exposed surface of the first source/drain region 130a and then heat-treated. Also, a process may be performed to induce a reaction between the first source/drain region 130a and the metal constituting the metal liner. After the metal silicide film is formed, the remaining portion of the metal liner may be removed. During the process of forming the metal silicide film, a portion of the first source/drain region 130a may be consumed. In some embodiments, the backside barrier film 194 and the backside via 196 may be formed and heat-treated, and a metal silicide film may be formed through a reaction between the first source/drain region 130a and the metal constituting the backside barrier film 194.

Subsequently, a lower insulating film 198 may be formed to cover the backside contact DBC, the gap-fill insulating film 192, and the plurality of device isolation films 112. Also, a lower wiring film M2 may be formed to pass through the lower insulating film 198 and electrically connected to and/or contact the backside contact DBC.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a plurality of device isolation films extending lengthwise in a first horizontal direction and spaced apart from each other in a second horizontal direction intersecting the first horizontal direction;
a gap-fill insulating film located between the plurality of device isolation films;
a plurality of gate lines disposed above the gap-fill insulating film and extending lengthwise in the second horizontal direction;
a plurality of source/drain regions comprising a first source/drain region and a second source/drain region, each of the plurality of source/drain regions located between the plurality of gate lines;
a backside contact provided below the first source/drain region, the backside contact extending through the gap-fill insulating film and electrically connected to the first source/drain region; and
a gate protective film provided below the first source/drain region and being in contact with an upper sidewall of the backside contact,
wherein at least a portion of a sidewall of the gate protective film is surrounded by the gap-fill insulating film.

2. The integrated circuit device of claim 1, wherein the gate protective film comprises SiGe, SiGeC, SiO, SiC, SiOC, SiOCN, SiOH, GeC, or a combination thereof.

3. The integrated circuit device of claim 1, wherein the gate protective film comprises a silicon carbide film, and a carbon content in the gate protective film is about 3 at % to about 30 at %.

4. The integrated circuit device of claim 1, wherein each of the first source/drain region and the second source/drain region comprises:
a first semiconductor film; and
a second semiconductor film having a sidewall and a lower surface surrounded by the first semiconductor film,
wherein each of the first semiconductor film and the second semiconductor film comprises a Si film or a SiGe film.

5. The integrated circuit device of claim 4, wherein each of the first semiconductor film and the second semiconductor film comprises a SiGe film,
the gate protective film comprises a SiGe film,
a ratio of Ge contained in the gate protective film is greater than a ratio of Ge contained in the first semiconductor film, and
a ratio of Ge contained in the second semiconductor film is greater than the ratio of Ge contained in the first semiconductor film.

6. The integrated circuit device of claim 1, wherein the gate protective film covers a portion of a lower surface of the first source/drain region, and
the backside contact covers the other portion of the lower surface of the first source/drain region.

7. The integrated circuit device of claim 1, wherein the gate protective film has a sidewall opposite the backside contact, and
the sidewall of the gate protective film has a convex shape protruding in a direction receding from the backside contact.

8. The integrated circuit device of claim 1, wherein the gate protective film has a sidewall opposite the backside contact, and
the sidewall of the gate protective film has a pointed shape having a vertical thickness reducing in a direction receding from the backside contact.

9. The integrated circuit device of claim 1, wherein the gap-fill insulating film comprises a silicon oxide film, a silicon nitride film, or a silicon oxynitride film, and
the gap-fill insulating film surrounds a sidewall of the gate protective film.

10. The integrated circuit device of claim 1, wherein a portion of the backside contact, which overlaps the gate protective film in the first horizontal direction, has a horizontal width decreasing in a direction moving from a bottom to a top of the portion of the backside contact.

11. The integrated circuit device of claim 1, further comprising a gate dielectric film located between the plurality of source/drain regions and the plurality of gate lines,
wherein the gate protective film covers a portion of the gate dielectric film, which is adjacent to the backside contact.

12. The integrated circuit device of claim 1, further comprising a gate dielectric film located between the plurality of source/drain regions and the plurality of gate lines,
wherein the gate protective film is located between the gate dielectric film and the backside contact, and
the backside contact is spaced apart from the gate dielectric film with the gate protective film therebetween.

13. An integrated circuit device comprising:
a plurality of device isolation films extending lengthwise in a first horizontal direction and spaced apart from each other in a second horizontal direction intersecting the first horizontal direction;
a gap-fill insulating film located between the plurality of device isolation films;
a plurality of gate lines disposed above the gap-fill insulating film and extending lengthwise in the second horizontal direction;
a plurality of source/drain regions comprising a first source/drain region and a second source/drain region, each of the plurality of source/drain regions located between the plurality of gate lines;
a gate dielectric film located between the plurality of source/drain regions and the plurality of gate lines;
a gate protective film covering a portion of a lower surface of the gate dielectric film adjacent to the first source/drain region;
a gap-fill gate protective film covering a portion of a lower surface of the gate dielectric film adjacent to the second source/drain region; and
a backside contact being in contact with the gate protective film and electrically connected to the first source/drain region,
wherein the gate protective film and the gap-fill gate protective film are arranged between the gap-fill insulating film and the plurality of source/drain regions.

14. The integrated circuit device of claim 13, wherein each of the gate protective film and the gap-fill gate protective film comprises SiGe, SiGeC, SiO, SiC, SiOC, SiOCN, SiOH, GeC or a combination thereof.

15. The integrated circuit device of claim 13, wherein the gate protective film at least partially covers a lower surface of the first source/drain region, and
the gap-fill gate protective film completely covers a lower surface of the second source/drain region.

16. The integrated circuit device of claim 13, wherein a sidewall of the gate protective film and a sidewall and a lower surface of the gap-fill gate protective film are surrounded by the gap-fill insulating film, and
the gap-fill insulating film comprises a silicon oxide film, a silicon nitride film, or a silicon oxynitride film.

17. An integrated circuit device comprising:
a plurality of device isolation films extending lengthwise in a first horizontal direction and spaced apart from each other in a second horizontal direction perpendicular to the first horizontal direction;
a gap-fill insulating film located between two adjacent device isolation films among the plurality of device isolation films;
at least one nanosheet disposed above the gap-fill insulating film, spaced apart from an upper surface of the gap-fill insulating film in a vertical direction, and facing the upper surface of the gap-fill insulating film;
a gate line surrounding the at least one nanosheet above the gap-fill insulating film and extending lengthwise in the second horizontal direction intersecting the first horizontal direction;
a gate dielectric film surrounding the gate line and separating the at least one nanosheet from the gate line;
a first source/drain region and a second source/drain region, each disposed above the gap-fill insulating film and adjacent to the gate line and in contact with the at least one nanosheet;
a backside contact extending from a level of a lower surface of the gap-fill insulating film in the vertical direction to a lower surface of the first source/drain region and covering a portion of the lower surface of the first source/drain region;
a gate protective film located between the backside contact and the gap-fill insulating film and covering the other portion of the lower surface of the first source/drain region; and
a source/drain contact provided above the second source/drain region and electrically connected to the second source/drain region,
wherein the gap-fill insulating film comprises a silicon oxide film, and
the gate protective film comprises a silicon carbide film.

18. The integrated circuit device of claim 17, wherein the gate protective film includes carbon in an amount of about 3 at % to about 25 at %.

19. The integrated circuit device of claim 17, wherein the gate protective film has a sidewall opposite the backside contact, and
the sidewall of the gate protective film has a curved shape.

20. The integrated circuit device of claim 17, wherein the gate protective film has a sidewall opposite the backside contact, and
the sidewall of the gate protective film has a shape inclined diagonally between the first horizontal direction, the second horizontal direction, and the vertical direction.
